(19) United States
(12) Patent Application Publication
(10) Pub. No.: US 2013/0047923 A1
(43) Pub. Date: Feb. 28, 2013

(54) FILM DEPOSITION APPARATUS, SUBSTRATE PROCESSING APPARATUS, AND PLASMA GENERATING DEVICE

(71) Applicants: Hitoshi KATO, Iwate (JP); Takeshi KOBAYASHI, Iwate (JP); Shigehiro USHIKUBO, Iwate (JP); Katsuyoshi AIKAWA, Iwate (JP)

(72) Inventors: Hitoshi KATO, Iwate (JP); Takeshi KOBAYASHI, Iwate (JP); Shigehiro USHIKUBO, Iwate (JP); Katsuyoshi AIKAWA, Iwate (JP)

(73) Assignee: Tokyo Electron Limited, Tokyo (JP)

(21) Appl. No.: 13/588,271

(22) Filed: Aug. 17, 2012

(30) Foreign Application Priority Data
Aug. 24, 2011 (JP) 2011-182918

(51) Int. Cl. C23C 16/513

(52) U.S. Cl. 118/723 AN

(57) ABSTRACT

A disclosed film deposition apparatus which forms a film on a substrate inside a vacuum chamber including a turntable having a substrate mounting area, includes an antenna facing the substrate mounting area for converting the plasma generating gas to plasma, a Faraday shield intervening between the antenna and the substrate to prevent an electric field of an electromagnetic field from passing therethrough, the Faraday shield including slits arranged on the conductive plate parallel to the antenna, the slits being opened on the conductive plate in perpendicular to a direction of arranging the slits to enable a magnetic field to reach the substrate, a window opened in an area of the conductive plate surrounded by the slits, an inner conductive path between the slits and the window and grounded, and an outer conductive path on a side opposite to the window relative to the slits and surrounds the slits.

### CROSS-REFERENCE TO RELATED APPLICATIONS

This patent application is based upon and claims the benefit of priority of Japanese Patent Application No. 2011-182918 filed on Aug. 24, 2011, the entire contents of which are incorporated herein by reference.

### BACKGROUND OF THE INVENTION

1. Field of the Invention

The present invention generally relates to a film deposition apparatus, a substrate processing apparatus, and a plasma generating device.

2. Description of the Related Art

An exemplary method for forming a thin film such as a silicon oxide (SiO₂) film on a substrate such as a semiconductor wafer is an Atomic Layer Deposition (ALD) method. The ALD method is to laminate a reaction product on a surface of the semiconductor wafer by sequentially supplying plural kinds of process gases which are mutually reactive (reaction gases). For example, Patent Document 1 discloses a film deposition apparatus using the ALD method. Plural sheets of wafers are arranged in peripheral directions on a turntable provided in a vacuum chamber. Further, the turntable is rotated relative to plural gas supplying portions which are arranged so as to face the turntable. Thus, the plural process gases are sequentially supplied to the wafers.

With the ALD method, a heating temperature (a film deposition temperature) of the wafer is low enough to be about 300° C. in comparison with an ordinary Chemical Vapor Deposition (CVD) method. Therefore, an organic substance contained in the process gas may be taken as impurities into the thin film. For example, Patent Document 2 discloses alternation performed using plasma at a time of forming a thin film in order to remove impurities from a thin film or reduce impurities in a thin film.

If an apparatus for alternation using plasma is provided in addition to the film deposition apparatus, a wafer is transferred between the apparatus for alternation and the film deposition apparatus. This transfer causes a time loss to thereby lower a throughput of the wafers. Meanwhile, if a plasma source for generating plasma is combined with the film deposition apparatus to perform alternation while the film deposition process is performed or after the film deposition process ends, the plasma may damage wiring formed inside the wafers. If the plasma source is distanced from the wafers in order to suppress plasma damage to the wafers, activated species such as ion and radical inside the plasma are easily deactivated. Thus, the activated species hardly reach the wafers to possibly prevent good alternation.

Patent Documents 3 to 5 disclose apparatuses for forming a thin film using the ALD method but do not notice the above problems.
[Patent Document 1] Japanese Laid-open Patent Publication No. 2010-239102
[Patent Document 2] Japanese Laid-open Patent Publication No. 2011-40574
[Patent Document 3] U.S. Pat. No. 7,153,542
[Patent Document 4] Japanese Patent No. 3144664
[Patent Document 5] U.S. Pat. No. 6,869,641

### SUMMARY OF THE INVENTION

Accordingly, embodiments of the present invention may provide a film deposition apparatus, a substrate processing apparatus, and a plasma generating device, which can suppress plasma damage to a substrate in performing a plasma process for the substrate.

More specifically, the embodiment of the present invention may provide a film deposition apparatus which forms a film on a substrate by repeatedly performing a process of sequentially supplying a first process gas containing Si and a second process gas containing O₂ inside a vacuum chamber, the film deposition apparatus including a turntable including a substrate mounting area formed on one surface of the turntable to mount a substrate, the turntable being configured to rotate the substrate mounting area inside the vacuum chamber; a first process gas supplying portion for supplying the first process gas to a first area over the turntable; a second process gas supplying portion for supplying the second process gas to a second area over the turntable, the second area being separated, in a peripheral direction of the turntable, from the first area by a separating area being provided over the turntable and interposing between the first area and the second area; a plasma generating gas supplying portion protruding inside the vacuum chamber to supply a plasma generating gas containing Ar and O₂ used for applying plasma to the substrate inside the vacuum chamber; an antenna facing the substrate mounting area and being wound toward a direction perpendicular to the one surface of the turntable, the antenna being configured to convert the plasma generating gas to plasma using induction coupling; and a Faraday shield intervening between the antenna and the substrate and being made of a conductive plate which is grounded to prevent an electric field included in an electromagnetic field, which is generated around the antenna, from passing through the Faraday shield including: slits arranged on the conductive plate parallel to a loop of the antenna, the slits being opened on the conductive plate in directions perpendicular to a direction of arranging the slits to enable a magnetic field included in the electromagnetic field to reach the substrate, a window opened in an area of the conductive plate surrounded by the slits, the window is configured to enable observation of generation of the plasma, an inner conductive path which is formed between the slits and the window and grounded so as to prevent the window from communicating the slits, and an outer conductive path which is formed on a side opposite to the window relative to the slits and surrounds the slits.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view illustrating an exemplary film deposition apparatus of the embodiment;

FIG. 2 is a cross-sectional plan view of the film deposition apparatus;

FIG. 3 is a cross-sectional plan view of the film deposition apparatus;

FIG. 4 is an exploded perspective view schematically illustrating an inside of the film deposition apparatus;

FIG. 5 is a vertical cross-sectional view illustrating the inside of the film deposition apparatus;

FIG. 6 is a perspective view illustrating a part of the inside of the film deposition apparatus;

FIG. 7 is a vertical cross-sectional view partially omitted illustrating the inside of the film deposition apparatus;

FIG. 8 is a plan view illustrating the part of the inside of the film deposition apparatus;

FIG. 9 is a perspective view illustrating a Faraday shield of the film deposition apparatus;

FIG. 10 is a perspective view illustrating a part of the Faraday shield of the film deposition apparatus;

FIG. 11 is an exploded perspective view illustrating a side ring of the film deposition apparatus;

FIG. 12 is a vertical cross-sectional view illustrating a part of a labyrinth structure of the film deposition apparatus;

FIG. 13 is a horizontal cross-sectional view of the film deposition apparatus schematically illustrating gas flows inside the film deposition apparatus;

FIG. 14 schematically illustrates generation of plasma in the film deposition apparatus;

FIG. 15 is a vertical cross-sectional view partially omitted illustrating another exemplary film deposition apparatus;

FIG. 16 is a horizontal cross-sectional view of the film deposition apparatus schematically illustrating gas flows inside another exemplary film deposition apparatus;

FIG. 17 is a perspective view illustrating a part of the inside of another exemplary film deposition apparatus;

FIG. 18 is a plan view illustrating a part of the inside of another exemplary film deposition apparatus;

FIG. 19 is a vertical cross-sectional view illustrating a part of the inside of another exemplary film deposition apparatus;

FIG. 20 is a vertical cross-sectional view illustrating a part of the inside of the other exemplary film deposition apparatus;

FIG. 21 is a vertical cross-sectional view illustrating a part of the inside of the other exemplary film deposition apparatus;

FIG. 22 is a plan view of the film deposition apparatus schematically illustrating gas flows inside the other exemplary film deposition apparatus;

FIG. 23 is a plan view illustrating a part of the inside of another exemplary film deposition apparatus;

FIG. 24 is a perspective view illustrating a part of the inside of the film deposition apparatus;

FIG. 25 is a perspective view illustrating a part of the inside of the film deposition apparatus; and

FIG. 26 is a characteristic diagram illustrating results of simulation obtained by the embodiment.

### DETAILED DESCRIPTION OF THE PREFERRED EMBODIMENTS

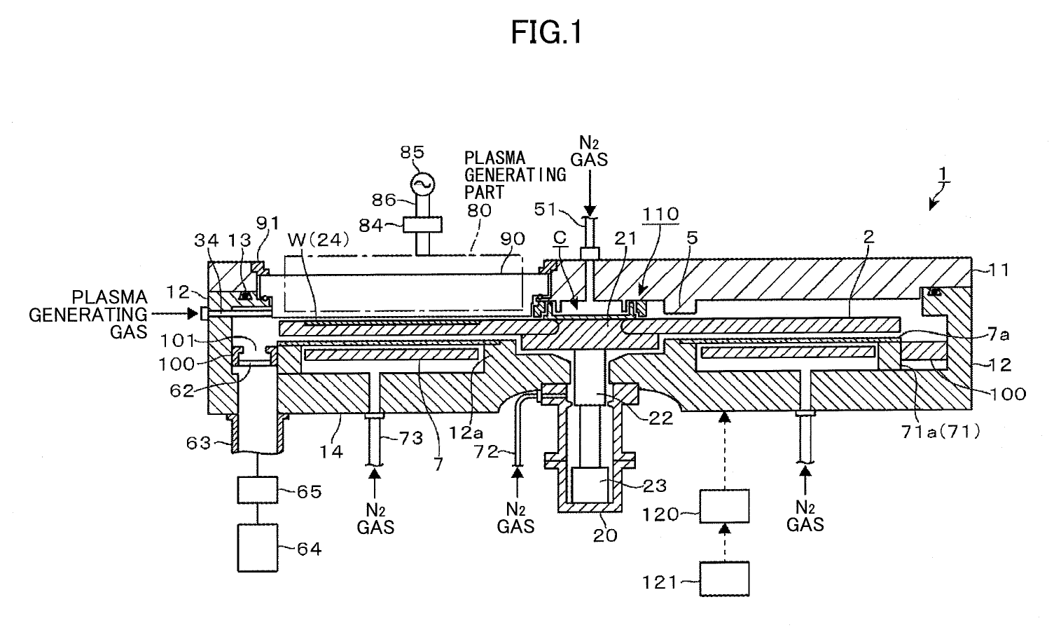

A description is given below, with reference to the FIG. 1 through FIG. 26 of embodiments of the present invention.

Hereinafter, the reference symbols typically designate as follows:
W: wafer;
P1, P2: processing area;
1: vacuum chamber;
2: turntable;
10: plasma space;
80, 81: plasma generating part;
83: antenna;
85: high frequency power source;
90: casing;
95: Faraday shield;
97: slit; and
97a: conductive path.

According to embodiments of the present invention, a Faraday shield made of a grounded conductor is located between an antenna for generating induction coupled plasma and a substrate being provided with the induction coupled plasma. The Faraday shield has slits formed in directions perpendicular to a loop of the antenna and arranged along the loop. Conductive paths are formed respectively on a side of first ends of the slits in their longitudinal directions and on a side of second ends of the slits in their longitudinal directions. Therefore, it is possible to prevent an electric field included in an electromagnetic field generated by the antenna from passing through the Faraday shield and to cause a magnetic field included in the electromagnetic field generated by the antenna to pass through the Faraday shield. Therefore, it is possible to prevent electric damage from being applied to the substrate.

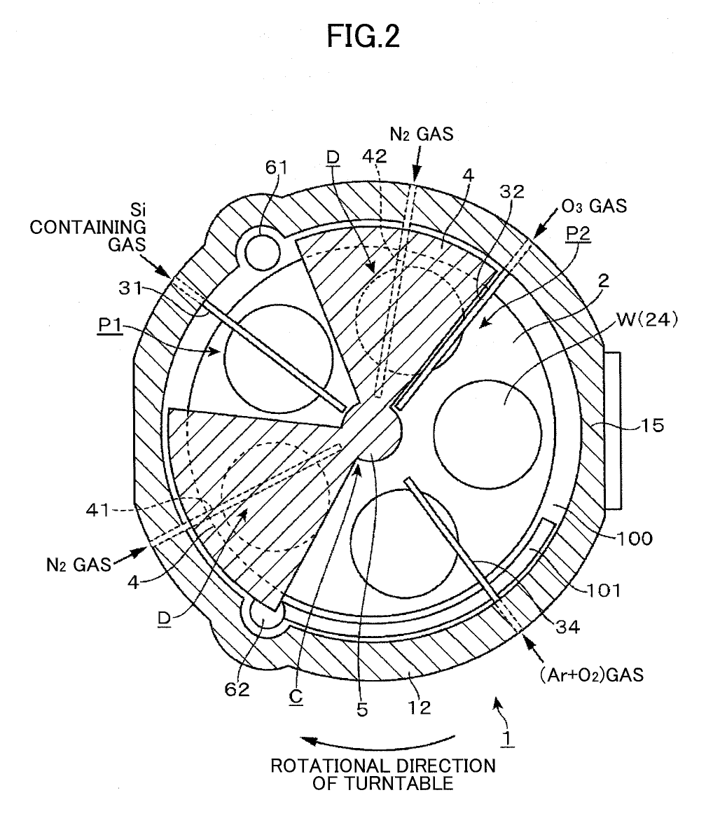

Referring to FIG. 1 to FIG. 12, a plasma generating device included in a film deposition apparatus (a substrate processing apparatus) of the embodiment is described. Referring to FIG. 1 and FIG. 2, the film deposition apparatus includes a vacuum chamber 1 substantially in a circular shape in its plan view and a turntable 2 which is a loading table being accommodated in the vacuum chamber 1 and having a rotation center in a center of the vacuum chamber 1. As described in detail later, the film deposition apparatus is configured to laminate a reaction product on a surface of a wafer W having a diameter of 300 mm by an ALD method to thereby form a thin film and simultaneously to perform alternation of the thin film using plasma. The film deposition apparatus is provided to prevent electric damage from applying to the wafer W by plasma or to reduce the electric damage as small as possible. Next, various parts of the film deposition apparatus is described in detail.

The vacuum chamber 1 includes a ceiling plate 11 and a chamber body 12. The ceiling plate 11 is configured to be attachable to or detachable from the chamber body 12. A separation gas supplying pipe 51 is connected to a center portion on an upper face side of the ceiling plate 11. A separation gas such as a nitrogen gas (a N₂ gas) is supplied from a separation gas supplying pipe 51 to prevent different gases from mixing in a center area C inside the vacuum chamber 1. Referring to FIG. 1, reference symbol 13 provided along a peripheral portion on an upper surface of the chamber body 12 is a sealing member. The sealing member 13 is, for example, an O ring.

A center portion of a turntable 2 is fixed to a core portion 21 substantially in a cylindrical shape. A rotational shaft 22 extending in a vertical direction is connected to the lower surface of the core portion 21. The turntable 2 is freely rotatable in a clockwise direction around a vertical axis of the rotational shaft. Referring to FIG. 1, a driving mechanism 23 is provided to rotate the rotational shaft 22 around the vertical axis, and a case body 20 accommodates the rotational shaft 22 and the driving mechanism 23. An upper flange portion of the case body 20 is hermetically attached to a lower surface of the bottom portion 14 of the vacuum chamber 1. A purge gas supplying pipe 72 is connected to a lower area of the turntable 2 so as to supply N₂ gas as a purge gas. A ring-shaped protrusion portion 12a of the bottom portion 14 of the vacuum chamber 1 surrounds the core portion 21. The ring-shaped protrusion portion 12a is shaped like a ring and approaches the lower surface of the turntable 2.

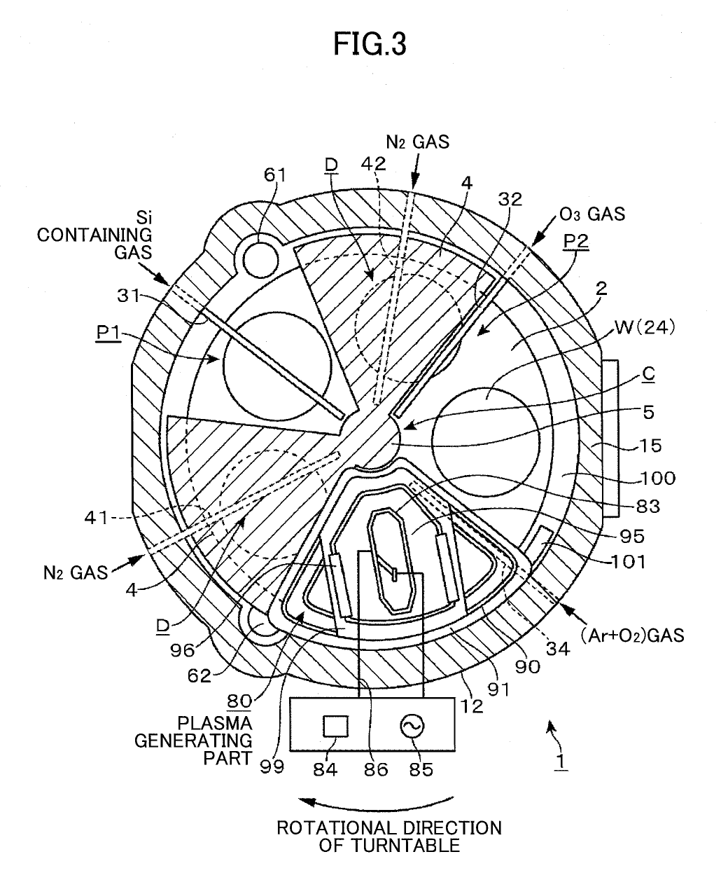

Referring to FIG. 2 and FIG. 3, circular concave portions shaped like a circle are provided on the surface of the turntable 2 along rotational directions (peripheral directions). The wafers W are mounted on the circular concave portions. The number of the circular concave portions is, for example, 5. The circular concave portion 24 is designed to have a diameter and a depth to enable surfaces of the wafers W to be arranged on a surface of portions of the turntable 2 where the wafers W are not mounted when the wafers W are dropped or accommodated into the circular concave portions 24. Through holes through which lift pins (described below) penetrate are provided respectively on bottom surfaces of the circular concave portions 24. The lift pins cause the wafers to be pushed up so that the wafers are moved up or down. The number of the lift pins is three.

Referring to FIG. 2 and FIG. 3, five nozzles 31, 32, 34, 41, and 42 are arranged radially in peripheral directions of the vacuum chamber 1 interposing a gap between the five nozzles 31, 32, 34, 41, and 42. The five nozzles 31, 32, 34, 41, and 42 face all of the circular concave portions 24 when the turntable 2 having the circular concave portions 24 is rotated once. A material of the vacuum chamber 1 may be quartz. These nozzles 31, 32, 34, 41, and 42 are attached to an outer peripheral wall of the vacuum chamber 1 toward the center area C so as to horizontally extend toward the center area C while facing the wafers W. The five nozzles 31, 32, 34, 41, and 42 may be a first process gas nozzle 31, a second process gas 32, a plasma generating gas nozzle 34, a separation gas nozzle 41, a separation gas nozzle 42. Referring to FIG. 2 and FIG. 3, the plasma generating gas nozzle 34, the separation gas nozzle 41, the first process gas nozzle 31, the separation gas nozzle 42, and the second process gas nozzle 32 are arranged in this order from a transfer opening 15 (described below) in a clockwise direction (a rotational direction of the turntable 2). Referring to FIG. 1, on an upper side of the plasma generating gas nozzle 34, a plasma generating part 80 is provided to convert a gas discharged from the plasma generating gas to plasma. The plasma generating part 80 is described later in detail.

The process gas nozzles 31 and 32 function as a first process gas supplying portion and a second process gas supplying portion, respectively. The separation gas nozzles 41 and 42 function as separation gas supplying portions, respectively. Referring to FIG. 2, the plasma generating part 80 and a casing 90 (described later) are omitted so that the plasma generating gas nozzle is observed. Referring to FIG. 3, the plasma generating part 80 and the casing 90 are attached. Referring to FIG. 1, the plasma generating part 80 is schematically illustrated by a dot chain line.

The nozzles 31, 32, 34, 41, and 42 are connected to corresponding gas supplying sources (not illustrated) via corresponding flow rate controlling valves. The first process gas nozzle 31 may be connected to the gas supplying source for supplying a first process gas containing silicon (Si) such as bis(tertiary-butylaminosilane) and a SiH₂(NH—C(CH₃)₃)₂) gas. The second process gas nozzle 32 may be connected to a gas supplying source for supplying a second process gas such as a mixed gas of an ozone gas (an O₃ gas) and an oxygen gas (a O₂ gas). The plasma generating gas nozzle 34 may be connected to a gas supply source for supplying a mixed gas of an argon gas (an Ar gas) and an O₂ gas. The separation gas nozzles 41 and 42 may be connected to a gas supplying source for supplying a separation gas such as a nitrogen gas (a N₂ gas). For convenience, hereinafter, an example where the second process gas is an O₃ gas is described. An ozonizer for generating the O3 gas (not illustrated) is provided to the second process gas nozzle 32.

Plural gas ejection holes 33 are formed on lower sides of the gas nozzles 31, 32, 41 and 42 along radius directions of the turntable 2. For example, an interval of the plural gas ejection holes 33 is equal. The plural ejection holes 33 may be formed on a side surface of the plasma generating gas nozzle 34 at equal intervals along a longitudinal direction of the plasma generating gas nozzle 34. The plural ejection holes 33 obliquely downward direct to an upper stream side in the rotational direction of the turntable 2 (a side of the second process gas nozzle 32) and to a downward side. The reason for this direction of the ejection holes 33 of the plasma generating gas nozzle 34 is described later. These nozzles 31, 32, 34, 41 and 42 are located over the turntable 2 with a distance between the lower sides of the nozzles 31, 32, 34, 41 and 42 and the upper surface of the turntable 2 is, for example, about 1 to 5 mm.

An area lower than the process gas nozzles 31 and 32 become a first process area P1 for causing the wafers W to absorb the Si containing gas and a second process area P2 where the Si containing gas absorbed in the wafers W reacts with the O₃ gas. The separation gas nozzles 41 and 42 are provided to form a separating area D for separating the first process area P1 and the second process area P2. Referring to FIG. 2 and FIG. 3, the ceiling plate 11 of the vacuum chamber 1 has a convex portion 4 substantially in a sector-like shape having a groove portion 43. The separation gas nozzles 41 and 42 are accommodated in the groove portion 43. A ceiling surface 44 is formed on both sides of the separation gas nozzles 41 and 42 along the peripheral direction of the turntable 2 to prevent the process gases from mixing each other. The ceiling surface 44 (a first ceiling surface 44) is one of lower surfaces of the convex portion 4. The convex portion 4 also has a second ceiling surface 45 which is another one of the lower surfaces of the convex portion 4 and positioned upper than the first ceiling surface 44. A peripheral portion of the convex portion 4 (a portion on a side of an outer edge of a vacuum chamber 1) faces the outer edge surface of the turntable 2 and is slightly apart from the chamber body. The peripheral portion of the convex portion 4 is bent in a shape like an “L” so as to prevent the process gases from mixing.

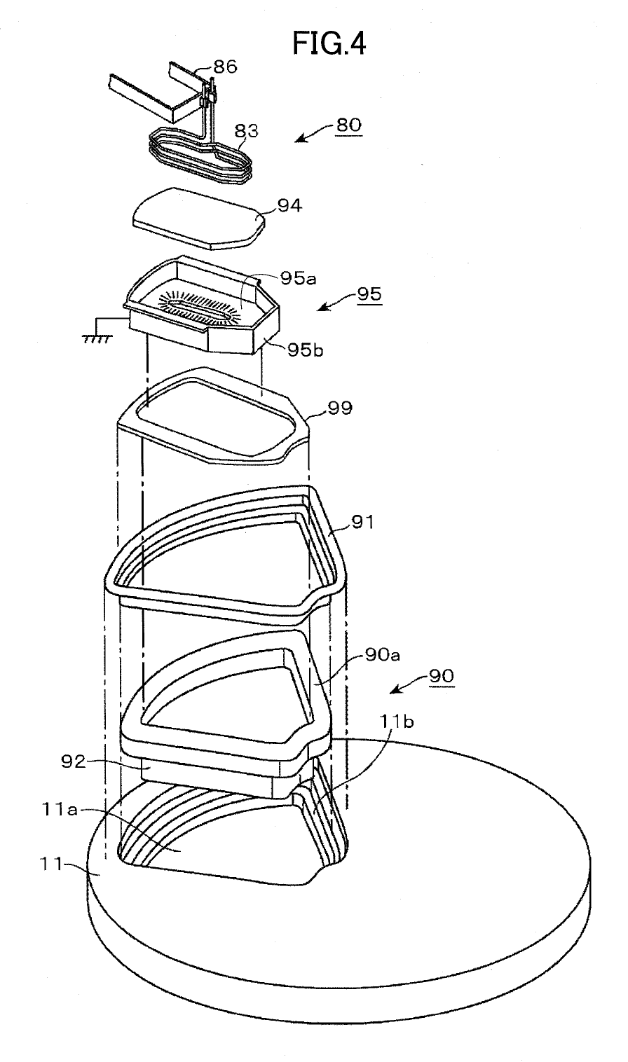

Next, the plasma generating part 80 is described in detail. The plasma generating part 80 is formed by winding an antenna 83 in a coil-like shape made of a metal, and is provided on the ceiling plate 11 of the vacuum chamber 1. The plasma generating part 80 is hermetically separated from an inside of the vacuum chamber 1. In this example, the antenna 83 is made by providing nickel plating or gold plating to a surface of, for example, copper (Cu). Referring to FIG. 4, the ceiling plate 11 has an opening portion 11a substantially in a sector shape in its plan view. The opening portion 11a positioned above the plasma generating gas nozzle 34, specifically on a range between a position on a slightly upstream side of the plasma generating gas nozzle 34 in the rotational direction of the turntable 2 and a position on the plasma generating gas nozzle 34 slightly from the separating area D along the rotational direction of the turntable 2.

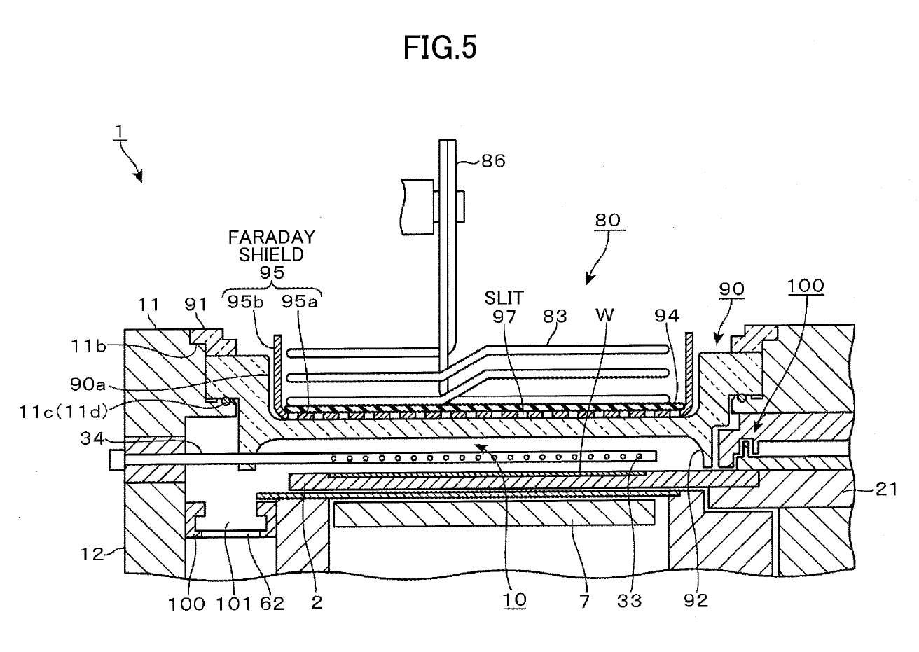

For example, the range of the opening portion 11a formed in the ceiling plate 11 is between, for example, a position apart by about 60 mm from the rotation center of the turntable 2 and a position apart by about 80 mm from the outer edge of the turntable 2. Further, the opening portion 11a is recessed like an arc so that an end of the opening portion 11a on the center side of the turntable 2 faces an outer edge of the labyrinth structure 110. Referring to FIG. 4 and FIG. 5, the opening portion 11a is formed by three step portions 11b. Opening sizes of three step portions 11b gradually decrease from an upper surface side of the ceiling plate 11 to a lower surface side. On an upper surface of the lowermost step portion among the step portions 11b, a groove 11c is formed in the peripheral direction as illustrated in FIG. 5. A sealing member such as an O ring 11d is accommodated inside the groove 11c. The groove 11c and the O ring 11d are omitted in FIG. 4.

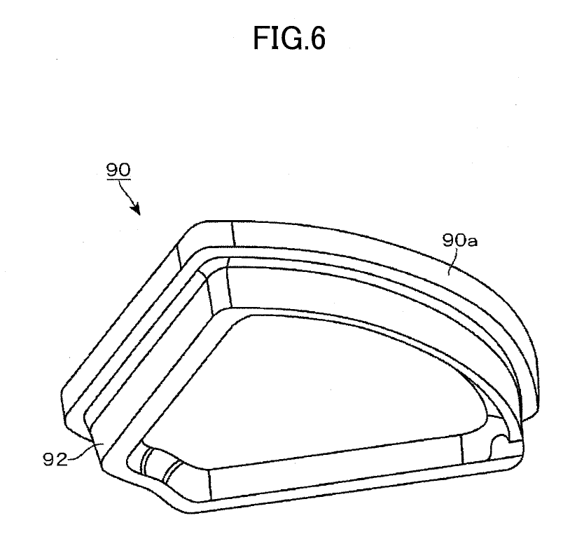

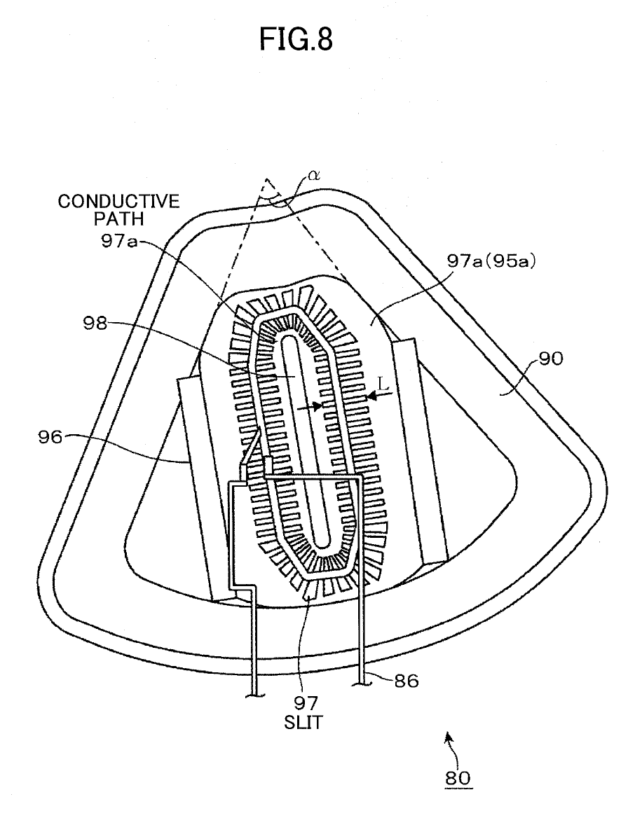

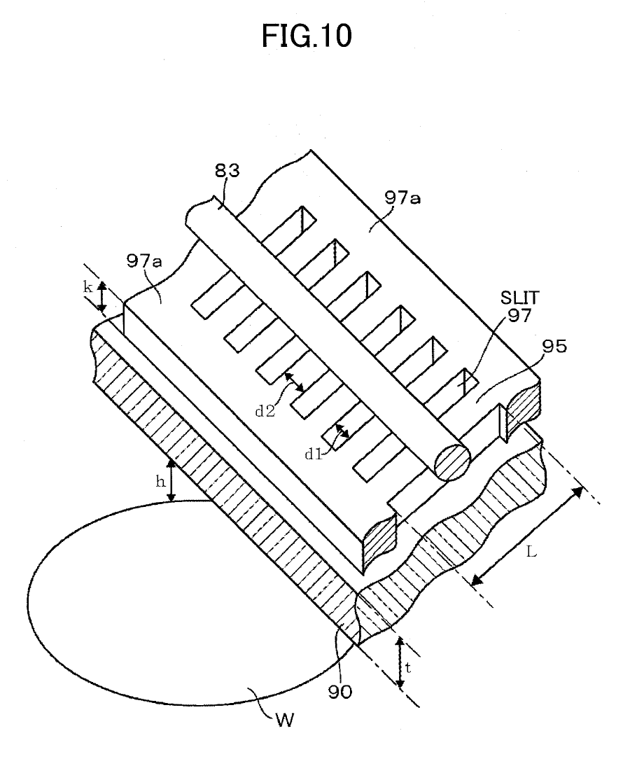

The casing 90 is installed in the opening portion 11a. Referring to FIG. 6, the casing 90 has a flange portion 90a provided along an upper periphery and protruding in the horizontal direction, and a center portion having an outer periphery narrower than the outer periphery of the flange portion 90a. The casing 90 is made of a material, permeable to magnetic force, like a dielectric material such as quartz for enabling a magnetic field generated by the plasma generating part 80 to reach inside the vacuum chamber 1. Referring to FIG. 10, the thickness t of the center portion of the casing is, for example, 20 mm. Further, when the wafer W is positioned below the casing 90, a distance between an inner wall surface of the casing 90 on the side of the center area C and the outer edge of the wafer W the casing is 70 mm, and a distance between an inner wall surface of the casing 90 on the outer peripheral side of the turntable 2 and the outer edge of the wafer W is 70 mm. Therefore, referring to FIG. 8, an angle α formed among the rotation center of the turntable 2 and two sides of the opening portions 11a on the upstream and downstream sides of the turntable 2 in the rotational direction of the turntable 2 is, for example, 68°.

When the casing 90 is installed inside the opening portion 11a, the flange portion 90a is engaged with the lowermost step portion among the step portions. With the O-ring 11d, the step portion 11b of the ceiling plate 11 is hermetically connected to the casing 90. Further, a pressing member 91 in a frame-like shape formed so as to correspond to the opening portion 11a is used to press the flange portion 90a through the entire periphery in a downward direction. Then, the pressed pressing member 91 is secured to the ceiling plate 11 by, for example, a screw (not illustrated) to thereby hermetically close the inner atmosphere of the vacuum chamber 1. Referring to FIG. 10, at this time of hermetically closing the inner atmosphere of the vacuum chamber 1, the distance h between the lower surface of the casing 90 and the upper surface of the wafer W on the turntable 2 may be 4 to 60 mm (30 mm in the above example). FIG. 6 is viewed from a lower side of the casing 90. Referring to FIG. 10, a part of the casing 90 is enlarged.

The lower surface of the casing 90 forms a protruding portion 92 for regulating gas. The protruding portion 92 prevents a N₂ gas or an O₃ gas from intruding into a lower region of the casing 90. For this, the outer edge of the protruding portion 92 protrudes in the downward direction toward the turntable 2 along the periphery of the protruding portion 92. In a region surrounded by the inner peripheral surface of the protruding portion 92, the lower surface of the casing 90 and the upper surface of the turntable 2, the plasma generating gas nozzle 34 is accommodated. The position of the plasma generating gas nozzle 34 is closer to the upper stream side of the rotational direction of the turntable 2.

In the lower region of the casing 90 (i.e., a plasma space), a gas supplied from the plasma generating gas nozzle 34 is converted to plasma. Therefore, if the N₂ gas intrudes into the lower region, the plasma of the N₂ gas reacts with the plasma of the O₃ (O₂) gas to thereby generate a NOₓ gas. When the NOₓ gas is generated, parts inside the vacuum chamber 1 may be decomposed. The protruding portion 92 is formed on the lower surface side of the casing to prevent the N₂ gas from intruding into a lower area of the casing 90.

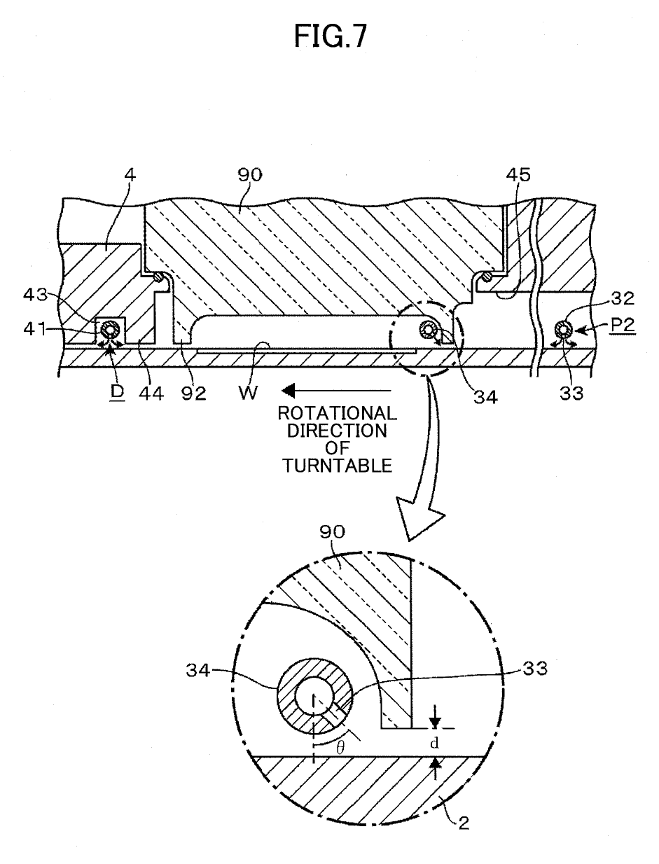

Referring to FIG. 6, a part of an outer peripheral side (a circumference side of a sector) of the protruding portion 92 is cut to be substantially in a shape of a circular arc to enable it to penetrate the plasma generating gas nozzle 34 through the outer peripheral side of the protruding portion 92. A distance d between the lower surface of the protruding portion 92 and the upper surface of the turntable is 0.5 to 4 mm, in this example, 2 mm. For example, the width and the height of the protruding portion 92 are 10 mm and 28 mm, respectively. FIG. 7 is a cross-sectional view of the vacuum chamber 1 cut along the rotational direction of the turntable 2.

Since the turntable 2 rotates in a clockwise direction during the film deposition process, the N2 gas tends to intrude into the lower side of the casing 90 from a gap between the turntable 2 and the protruding portion 92 along the rotation of the turntable 2. Therefore, a gas is discharged from the lower side of the casing 90 toward the gap in order to prevent the N₂ gas from intruding into the lower portion of the casing 90. Specifically, as illustrated in FIG. 5 and FIG. 7, a gas ejection hole 33 of the plasma generating gas nozzle 34 is arranged to obliquely direct the upper stream side of the rotational direction and the lower side of the turntable. Referring to FIG. 7, the angle θ of the oblique direction plasma generating gas relative of the vertical axis is, for example, about 45°.

Referring to FIG. 5, the protruding portion 92 is formed along an outer side between the plasma space 10 and the O-ring 11d, which seals an area between the ceiling plate 11 and the casing 90 on the lower side of the casing 90 (on a side of the plasma space 10). Therefore, the O-ring 11d is isolated from the plasma space 10 so that the O-ring 11d is not directly exposed to plasma. Therefore, plasma diffusing toward the O-ring 11d from the plasma space may be deactivated before reaching the O-ring 11d because the plasma passes through the lower side of the protruding portion 92 so as to be weakened.

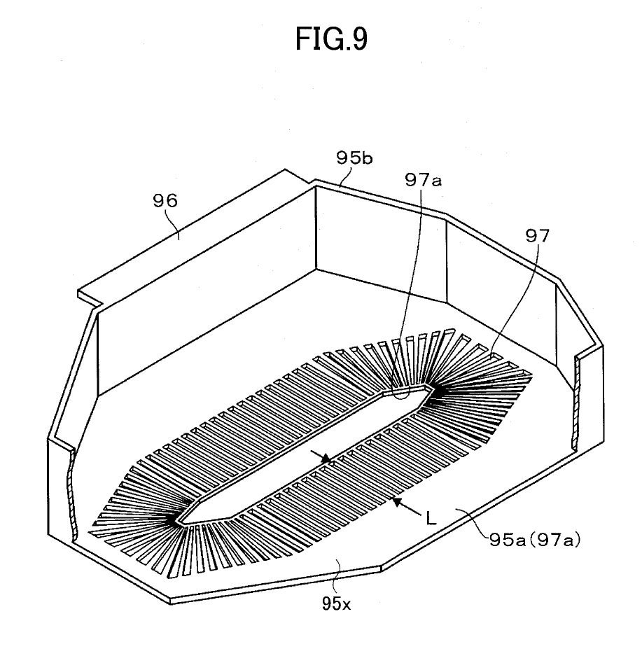

Referring to FIG. 4, FIG. 8, and FIG. 9, a Faraday shield 95 is substantially like a box with its top opened and accommodated inside the casing 90. The Faraday shield 95 is made of a conductive metallic plate having a thickness k of 0.5 mm to 2 mm, in this example, about 1 mm. Also in this example, the Faraday shield 95 is made of a plate formed by plating a nickel (Ni) film and a gold (Au) film below a copper (Cu) plate or a Cu film. The Faraday shield 95 includes a horizontal surface 95a horizontally formed along a bottom surface of the casing 95 and a vertical surface 95b extending upward from an entire outer peripheral edge of the horizontal surface 95a. The Faraday shield 95 is formed to be in a hexagonal shape when the Faraday shield 95 is viewed from the upper side of the Faraday shield 95 (a hexagonal shape in the plan view). An opening portion 98 is formed as a window at a center portion on a horizontal surface 95a. The opening portion 98 is substantially shaped like an octagon. The opening portion 98 is provided to enable a shape like an octagon. A horizontal surface allows an operator to watch generation of plasma (light emitting state) inside the vacuum chamber 1 via the insulating plate 94 and the casing 90 from an upper side of the vacuum chamber 1. For example, the Faraday shield 95 is formed by pressing a metallic plate and bending upward a peripheral part of the metallic plate (horizontal surface 95a). Referring to FIG. 4, the structure of the Faraday shield 95 is simplified. Referring to FIG. 8, a part of the vertical surface 95b is omitted.

Upper flanges of the Faraday shield 95 horizontally protrude on right and left sides relative to the rotation center of the turntable 2, respectively. The upper flanges of the Faraday shield 95 form supporting portions 96. A frame 99 is provided between the Faraday shield 95 and the casing 90. The frame 99 is supported by the flange portion 90a on the side of the center area C of the casing 90 and on the outer peripheral side of the turntable 2. Therefore, when the Faraday shield 95 is accommodated inside the casing 90, the lower surface of the Faraday shield 95 contacts the upper surface of the casing 90, and the supporting portion 96 is supported by the flange portion 90a of the casing 90 via the frame 99.

The insulating plate 94 is made of quartz of a thickness of about 2 mm is laminated on the horizontal surface 95a of the Faraday shield 95 to insulate the plasma generating part 80 from the Faraday shield 95. The many slits 97 are formed on the horizontal surface 95a. The conductive paths 97a are formed on the side of the one ends of the slits 97 and the side of the other ends of the slits 97. The shapes and the layout of the slits 97 and the conductive path 97a are described in detail in association with the shape of the antenna 83 of the plasma generating part 80. The insulating plate 94 and the frame 99 are omitted in FIG. 8 and FIG. 10.

Referring to FIG. 4 and FIG. 5, the plasma generating part 80 is accommodated inside the Faraday shield 95 so as to face the inside of the vacuum chamber 1 (the wafer W on the turntable 2) via the casing 90, the Faraday shield 95 and the insulating plate 94. The plasma generating part 80 includes the antenna 83 which is shaped like an elongated octagon surrounding the opening portion 98 on the Faraday shield 95 in a plan view of the antenna 83. The antenna 83 is wound three times to be shaped like the elongated octagon and stand in a direction perpendicular to the surface of the turntable 2 toward the plasma space 10. Therefore, the antenna 83 is arranged along the surface of the wafer W on the turntable 2.

The ends of antenna 83 on the side of the center area C and the ends on the outer periphery of the turntable 2 are arranged so as to approach an inner peripheral surface of the casing 90. With this, the plasma can be applied between the side of the center area C and the ends on the outer periphery of the turntable 2 when the wafer W is positioned below the plasma generating part 80. The distance between both ends of the plasma generating part 80 in the rotational direction of the turntable 2 is made smaller in order to reduce the width of the casing 90 in the rotational direction of the turntable 2. In order to make the magnetic field generated by the plasma generating part 80 reach the inside of the vacuum chamber 1, the casing 90 is made of a highly pure quartz. Further, the casing 90 is formed to have a size greater than the antenna 83 in its plan view so that a part made of quartz is positioned below the antenna 83. Therefore, as the size of the antenna 83 in its plan view becomes greater, the size of the casing 90 below the antenna 83 needs to be increased to thereby increase the cost for the plasma device (the casing 90). Meanwhile, if the size of the antenna 83 in the radius direction of the turntable 2 is reduced, for example the antenna 83 is arranged on the center area C or on the side of the an outer edge of the turntable 2, the amount of the plasma applied to the wafer W becomes uneven on the surface of the wafer W. Within the embodiment of the present invention, sides of the antenna 83 on the upstream and downstream sides along the rotational direction of the turntable 2 mutually approach so that the plasma is evenly applied to the wafer W throughout the surface of the wafer W and the size of the casing 90 can be reduced in the plan view of the antenna 83. Specifically, the shape like the elongated octagon in the plan view of the antenna 83 has a longitudinal dimension of, for example, 290 mm to 330 mm and a dimension perpendicular to the longitudinal dimension is, for example, 80 mm to 120 mm. A flow passage (not illustrated) is formed inside the antenna 83 to flow cooling water.

The antenna 83 is connected to a high frequency power source 85 of which output power is 5000 W at a frequency of 3.56 MHz, for example, via a matching box 84. Referring to FIG. 1, FIG. 2 and FIG. 3, a connection electrode 86 is provided to electrically connect the plasma generating part 80 with the matching box 84 and the high frequency power source 85.

Referring to FIG. 8 and FIG. 9, the slits 97 of the Faraday shield 95 are described. The slits 97 are provided to prevent the electric field of the electromagnetic field generated by the plasma generating part 80 from reaching the wafer W and to cause the magnetic field of the electromagnetic field to reach the wafer W. If the electric field reaches the wafer W, electric wiring formed inside the wafer W may be electrically damaged. On the other hand, since the Faraday shield 95 is made of a grounded metallic plate, the slits 97 are formed so as not to shield the magnetic field in addition to the electric field. If a great opening portion is formed below the antenna 83, not only the magnetic field but also the electric field passes through the great opening portion. Therefore, in order to shield the electric field and cause the magnetic field to pass through the Faraday shield 95, the slits 97 having the dimensions and the layout are formed as described below.

Specifically, referring to FIG. 8, the slits 97 are formed below the antenna 83 in directions perpendicular to the loop of the antenna and arranged along the loop below the antenna 83. Therefore, the slits 97 in a shape of a straight line are partly formed along tangential lines of circles included in the turntable 2 substantially in a middle of the length of the antenna 83 along the radius direction of the turntable 2. Therefore, the slits 97 in a shape of a straight line are partly formed along the length of the antenna 83 substantially in ends of the length of the antenna 83. The other slits 97 positionally corresponding to corners of the antenna 83 directly perpendicular to the antenna 83 and slant relative to the peripheral direction and the radius direction of the turntable 2. Further, the widths of the slits 97 on the center area C and on the outer edge of the turntable 2 gradually decrease from the outer side of the loop to the inner side of the loop to increase the number of the slits as many as possible without causing intervals between the slits. Thus, there are many slits 97 along the longitudinal direction of the antenna 83.

The high frequency power source 85 of the frequency of 13.56 MHz (the wavelength of 22 m) is connected to the antenna 83. Therefore, the slits 97 are designed to have a width of 1/10000 or less of the wavelength. Referring to FIG. 10, the slits 97 have a width d1 of 1 mm to 6 mm, in this example 2 mm, and a distance between the slits d2 is 2 mm to 8 mm, in this example 2 mm. Referring to FIG. 8, the slits have a length L of 40 mm to 120 mm, in this example 60 mm, in a direction perpendicular to the loop of the antenna 83. Right and left ends along the length L of the slits 97 are positioned at about 30 mm from the loop of the antenna 83. Therefore, conductive paths 97a, 97a are positioned on the right and left ends along the length L of the slits 97. The conductive paths 97a, 97a are parts of the Faraday shield 95 along the loop of the antenna 83. Said differently, the conductive paths 97a, 97a are provided to close both ends of the slits 97 to prevent the right and left sides of the slits 97 from opening. The widths of the conductive paths are about 1 mm to 4 mm, in this example 2 mm. The reason why the conductive paths 97a, 97a are provided is described in detail using the conductive path 97a formed inside the antenna 83.

As described, the slits 97 shield the electric field of the electromagnetic field generated by the antenna 83 and enable the magnetic field of the electromagnetic field to pass through the Faraday shield. For shielding the electric field by preventing the electric field from reaching the wafer W and for enabling the magnetic field of the electromagnetic field to pass through the Faraday shield 95 as much as possible, it is preferable to make the lengths of the slits 97 as long as possible. However, in order to reduce the size of the casing in the rotational direction of the turntable 2 as small as possible, the antenna 83 is shaped like the elongated octagon. Thus, the end of the upper stream side of the antenna 83 and the end of the lower stream side of the antenna 83 are close. The opening portion 98 for observing the light emission of the plasma is formed on the horizontal surface 95a of the Faraday shield 95 so as to surround the antenna 83. Thus, the lengths L of the slits 97 may not be sufficient to shield the electric field generated by the antenna 83 inside the antenna 83. On the other hand, if the lengths L of the slits 97 are increased without providing the conductive path 97a, the electric field leaks on the side of the wafer W via opened ends of the slits. Therefore, in the embodiment, the opened ends of the slits 97 are closed by the conductive path 97a in order to prevent the electric field from leaking on the side of the wafer W inside the antenna 83. Therefore, the electric field downward directing inside the antenna 83 is modified so that an electric flux line is closed by the conductive path 97a to thereby prevent the electric field from intruding into the wafer W. The conductive path 97a outside the antenna 83 is provided by a reason similar to the conductive path 97a inside the antenna 83 to thereby prevent the electric field from leaking from outer ends of the slits 97. As described, the slits 97 are surrounded by the conductors along the loop of the antenna in the plan view of the Faraday shield 95.

Within the example, the opening portion 98 is formed on the area surrounded by the conductive path 97a (the area surrounded by the slits 97) inside the antenna 83. Via the opening portion 98, light emission by plasma inside the vacuum chamber 1 can be visually checked or checked by a camera (not illustrated). Referring to FIG. 3, the slits 97 are omitted. Referring to FIG. 4 and FIG. 5, the slits 97 are not fully illustrated. The number of the slits 97 may be, for example, about 150. The antenna 83, the slits 97 and the Faraday shield 95 having conductive paths 97a form the plasma generating device.

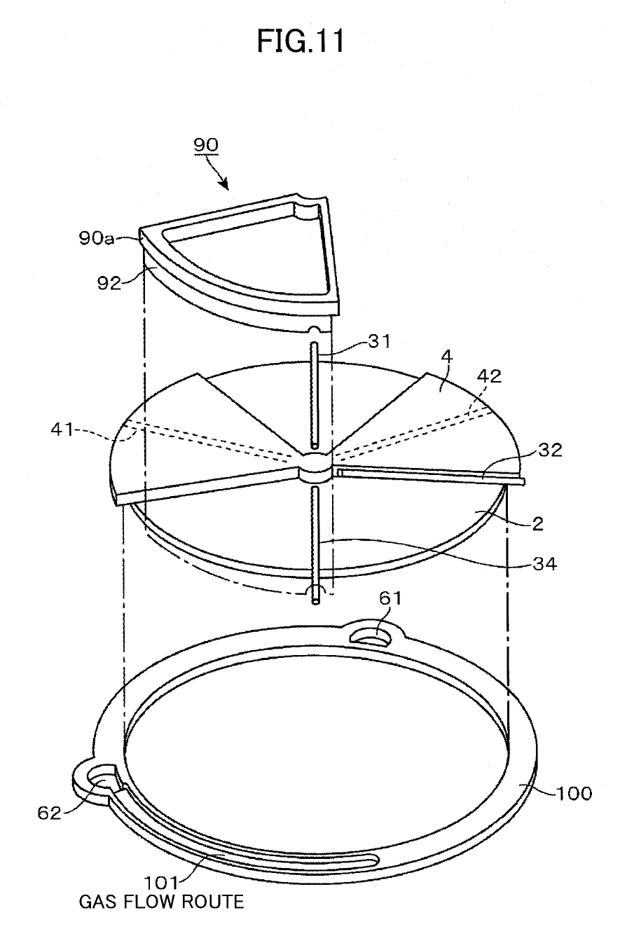

Subsequently, various portions of the vacuum chamber 1 are described. Referring to FIG. 2, FIG. 5 and FIG. 11, a side ring 100 being a cover is positioned slightly lower than the turntable 2 on an outer peripheral side of the turntable 2. The side ring 100 is provided to protect the inner wall of the vacuum chamber 1 from a fluorochemical cleaning gas flown instead of the process gases used at a time of cleaning the film deposition apparatus, for example. If the side ring 100 is not provided, a ring-like recessed flow path for flowing exhaust gas or air is formed between the outer periphery of the turntable 2 and the inner wall of the vacuum chamber 1. Therefore, the side ring 100 is formed along this ring-like recessed flow path to prevent the inner wall surface from being exposed. In this example, the separating area D and the outer edge of the casing 90 are positioned above the side ring 100.

Two evacuation ports 61 and 62 are formed on the side ring 100. The evacuation ports 61 and 62 are separated in the peripheral direction of the side ring 100. Said differently, two exhaust routes may be formed below the ring-like recessed flow path. Actually, the evacuation ports 61, 62 corresponding to the two exhaust routes are formed in the side ring 100. The two evacuation ports include a first evacuation port 61 and a second evacuation port 62. The first evacuation port 61 is positioned on a side closer to the separating area D between the first process gas nozzle 31 and the separating area D positioned on the downstream side of the first process gas nozzle 31 in the rotational direction of the turntable 2. The second evacuation port 62 is positioned on a side closer to the separating area D between the plasma generating gas nozzle 34 and the separating area D positioned on the downstream side of the plasma generating gas nozzle 34 in the rotational direction of the turntable 2. The first evacuation port 61 is provided to exhaust the first process gas and the separation gas. The second evacuation port 62 is provided to exhaust the plasma generating gas in addition to the second process gas and the separation gas. The first and second evacuation ports 61 and 62 may be connected to a vacuum pump 64 being a vacuum exhausting mechanism via evacuation pipes 63 and a pressure controller 65 such as a butterfly valve.

Since the casing 90 is formed from the side of the center area C to the outer edge side, gases discharged on the upper stream side of the rotational direction of the turntable 2 relative to the casing 90 are prevented by the casing 90 from flowing toward the second evacuation port 62. Therefore, a gas flow route 101 for flowing the second process gas and the separation gas is formed on the upper surface of the side ring 100 of the casing 90. Specifically, referring to FIG. 3, the gas flow route 101 is shaped like an arc between a position about 60 mm closer to the second process gas nozzle 32 from the end of the casing 90 on the upper stream side of the rotational direction of the turntable 2 to the second evacuation port 62. The depth of the gas flow route 101 is, for example, 30 mm. Therefore, the gas flow route 101 is formed along the outer edge of the casing 90 so as to bridge the upper and lower stream sides of the casing 90 in the plan view of the casing 90. In order to maintain corrosion resistance to a fluorine gas, the side ring 100 may be coated with alumina or covered by a quartz cover.

Referring to FIG. 2, a ring-shaped protrusion portion 5 is provided at a center portion below the ceiling plate 11. The ring-shaped protrusion portion 5 which is substantially shaped like a ring is continuously formed from the center area C of the convex portion 4. The lower surface of the ring-shaped protrusion portion 5 has the same height as the lower surface of the convex portion 4 and the ceiling surface 44. A labyrinth structure 110 is formed on the upper side of a core portion 21 and on the rotation center side of the turntable 2 from the ring-shaped protrusion portion 5. The labyrinth structure 110 prevents the first process gas and the second process gas from being mutually mixed. Referring to FIG. 1, the labyrinth structure 110 is formed closer to the center area C of the casing 90, and the core portion 21 is positioned closer to the rotation center side so that an upper portion of the turntable 2 prevents the casing 90. Therefore, on the side of the center area C of the convex portion 4, the process gases tend to be mixed in comparison with the side of the outer edge of the convex portion 4. By forming the labyrinth structure 110, a gas flow passage is further provided to thereby prevent the process gases from being mutually mixed.

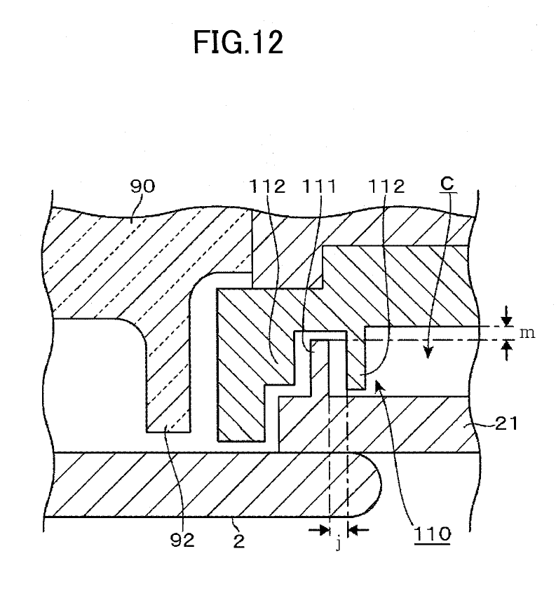

Specifically, referring to FIG. 12, the labyrinth structure 110 includes first walls 111 vertically extending from the turntable 2 toward the ceiling plate 11 and second walls 112 vertically extending from the ceiling plate 11 toward the turntable 2. The first walls 111 and the second walls 112 are formed along the peripheral direction respectively and alternately arranged in the radius directions of the turntable 2. Specifically, the second wall 112, the first wall 111 and the second wall 112 are arranged in this order from the ring-shaped protrusion portion 5 to the center area C. In this example, the second wall 112 on the ring-shaped protrusion portion 5 is thicker than the other first and second walls 111 and 112 toward the ring-shaped protrusion portion 5. For example, the distance j between the first and second walls 111 and 112 is 1 mm, a distance m between the first wall 111 and the ceiling plate 11 (a distance m between the second wall 112 and the core portion 21) is 1 mm. Therefore, when the first process gas is discharged from the first process gas nozzle 31 and directs the center area C, the first process gas is prevented from intruding through the first and second walls 111 and 112 into the center area C to thereby reduce a flow velocity and prevent diffusion. Therefore, before the process gas reaches the center area C, the process gas is pushed back by the separation gas supplied to the center area C toward the processing area P1. The second process gas directing the center area C cannot easily reach the center area C due to the existence of the labyrinth structure 110. Thus, the process gases are prevented from mutually mixing in the center area C.

Meanwhile, the N₂ gas supplied from the upper side of the center area C tends to swiftly spread toward the peripheral directions. However, the labyrinth structure 110 suppresses the flow velocity of the N₂ gas while the N₂ gas overflows the first and second walls 111 and 112. At this time, the N₂ gas may intrude into a very narrow area between the turntable 2 and the protruding portion 92. However, since the flow velocity is suppressed by the labyrinth structure 110, the N₂ gas flows toward an area (e.g., the processing areas P1 and P2) wider than the very narrow area. Therefore, the N₂ gas is prevented from intruding into a lower side of the casing 90. Further, as described below, a space on the lower side of the casing 90 (a plasma space 10) is set to have a positive pressure in comparison with other areas inside the vacuum chamber 1. Therefore, the N₂ gas is prevented from intruding into the plasma space.

A heater unit 7 being a heating mechanism is provided in a space between the turntable 2 and a bottom portion 14 of the vacuum chamber 1. The wafer W on the turntable 2 is heated via the turntable 2 to be, for example, about 300° C. Referring to FIG. 1, a side of the heater unit 7 is covered by a cover member 71a, and an upper side of the heater unit 7 is covered by a cover member 7a. Purge gas supplying pipes 73 for purging areas of the heater units 7 are provided at plural positions under the heater units 7. The purge gas supplying pipes 73 are connected to the bottom portion 14 of the vacuum chamber 1 and arranged in a peripheral direction of the bottom portion 14.

Referring to FIG. 2 and FIG. 3, a transfer opening 15 is formed in a side wall of the vacuum chamber 1. The transfer opening 15 is provided to deliver or receive a wafer W between a transfer arm (not illustrated) located outside the transfer opening 15 and the turntable 2. The transfer opening 15 can be opened or hermetically closed using a gate valve G. Further, lift pins (not illustrated) for lifting the wafers W from the back surfaces of the wafers W and lifting mechanisms (not illustrated) are provided in the circular concave portions 24 of the turntable 2. The wafers W are delivered and received at a position corresponding to the transfer opening 15. Therefore, the lift pins penetrate the circular concave portions 24 from a lower surface of the turntable 2 to lift the wafers W to the position where the wafers W are delivered and received with the transfer arm.

The film deposition apparatus includes a control portion 120 having a computer for controlling entire operations of the film deposition apparatus. A program for performing the film deposition process is stored in a memory of the control portion 120. The program is made to perform steps of the following operations. The program is installed in the control portion 120 from a memory unit 121 being a recording medium such as a hard disk, a compact disk, a magneto-optical disk, a memory card, and a flexible disk.

Next, functions of the embodiment are described. At first, the gate valve G is released. While the turntable 2 is intermittently rotated, five sheets of wafers W are mounted in the turntable 2 by the transfer arm via the transfer opening 15. The wafers W have undergone wiring embedding process using dry etching or chemical vapor deposition (CVD). Therefore, an electric wiring structure is formed inside the wafers W. Next, the gate valve G is closed to suction air inside the vacuum chamber 1 by a vacuum pump 64. While the turntable 2 is rotated in a clockwise direction, the wafers W are heated to be about 300° C. by the heater unit 7.

Subsequently, Si containing gas and O₃ gas are discharged from process gas nozzles 31 and 32, and a mixed gas of Ar gas and O₂ gas is discharged from the plasma generating gas nozzle 34. A separation gas is supplied at a predetermined flow rate from the separation gas nozzles 41 and 42. Further, N₂ gas is supplied at a predetermined flow rate from the separation gas supplying pipe 51 and the purge gas supplying pipes 72, 72. The inside of the vacuum chamber 1 is adjusted to have a predetermined processing pressure by a pressure controller 65. Further, high-frequency power is supplied to the plasma generating part 80.

At this time, the O₃ gas and the N₂ gas flowing toward the casing 90 along the rotation of the turntable 2 from the upper stream side of the turntable 2 relative to the casing 90 is disrupted by the existence of the casing 90. However, since the gas flow route 101 is formed in the side ring 100 on the outer peripheral side of the casing 90, the O₃ gas and the N₂ gas pass through the gas flow route 101 so as to be exhausted by passing over the casing 90.

A part of a gas flowing from the upper stream side of the casing 90 to the casing 90 tends to intrude below the casing 90. However, the protruding portion 92 is formed to cover an area below the casing 90, and the ejection holes 34 of the plasma generating gas nozzle 34 are directed obliquely downward on the upstream side of the rotational direction of the turntable 2. Therefore, the plasma generating gas discharged from the plasma generating gas nozzle 34 crashes against a lower portion of the protruding portion 92 and drives the O₃ gas and the N₂ gas flowing from the upstream side of the rotational direction to an outside of the casing 90. The plasma generating gas is pushed on the downstream side of the rotational direction of the turntable 2 by the protruding portion 92. By providing the protruding portion 92, the plasma space 10 below the casing 90 has a positive pressure by about 10 Pa more than the other areas inside the vacuum chamber 1. Thus, the O₃ gas and the N₂ gas are prevented from intruding below the casing 90.

Although the Si containing gas and the O₃ gas tend to intrude into the center area C, the labyrinth structure 110 in the center area C prevents the gas flow as described above and the Si containing gas and the O₃ gas are pushed back toward the processing areas P1 and P2 by the separation gas downward supplied to the center area C. Therefore, the process gases are prevented from mixing in the center area C. Further, the labyrinth structure 110 prevents the N₂ gas discharged onto the outer peripheral side of the center area from intruding into the lower side of the casing 90.

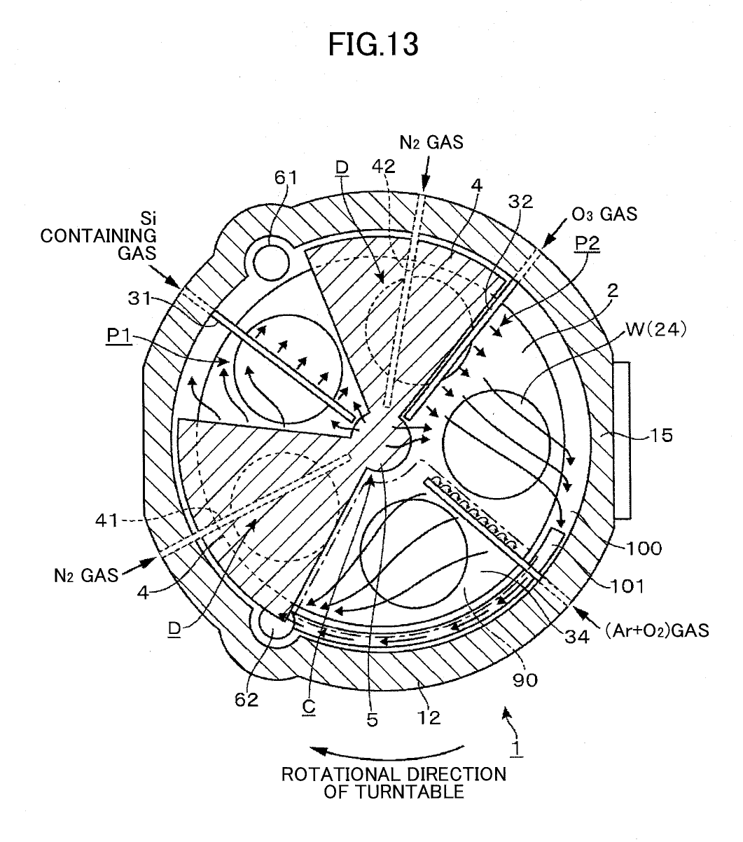

Further, the N₂ gas is supplied between the first process area P1 and the second process area P2. Referring to FIG. 13, since the N₂ gas is supplied between the processing area P1 and the second process area P2, the gases are exhausted so that the Si containing gas is not mixed with the plasma generating gas. Further, since the purge gas is supplied to the lower side of the turntable 2, the exhaust gas diffusing below the turntable 2 is pushed back toward the evacuation ports 61 and 62.

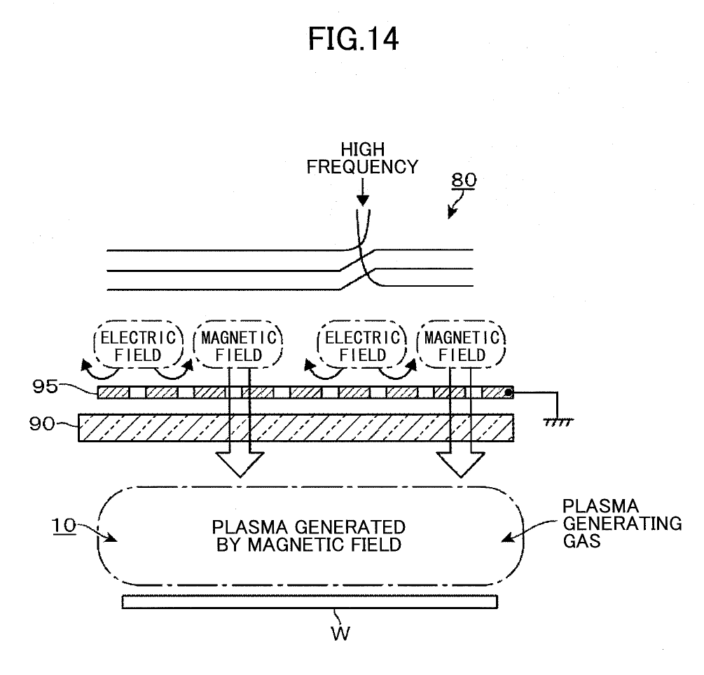

At this time, the plasma generating part 80 generates the electric field and the magnetic field by the high-frequency power supplied from high frequency power source 85 as schematically illustrated in FIG. 14. As described above, the Faraday shield 95 reflects, absorbs or attenuates the electric field to prevent the electric field from reaching inside the vacuum chamber 1 without shielding the magnetic field. Thus, the electric field is shielded and the magnetic field is not shielded. The electric field tends to go to the wafer W from the one ends and the other ends along the longitudinal directions of the slits 97. However, the conductive paths 97, 97 provided on the one end and the other end along the longitudinal direction of each of the slits 97 cause the electric field to be absorbed as heat thereby preventing the electric field from reaching the wafer W. Meanwhile, the magnetic field reaches the inside of the vacuum chamber 1 after passing the slits 97 of the Faraday shield 95 and the bottom surface of the casing 90. Since the slits 97 are not formed on the vertical surface 95b of the Faraday shield 95, the electric field and the magnetic field generated by the plasma generating part 80 cannot horizontally pass through the vertical surface 95b of the Faraday shield 95. Thus, the electric field and the magnetic field do not reach the lower side of the casing 90 from the vertical surface 95b of the Faraday shield 95.

Therefore, the plasma generating gas discharged from the plasma generating gas nozzle 34 is activated by the magnetic field to thereby generate plasma such as ions and radicals. As described, since the antenna 83 is arranged in the radius direction of the turntable 2, the plasma may be shaped substantially like a line in the radius direction of the turntable. Referring to FIG. 14, the plasma generating part 80 is schematically illustrated. Sizes of the plasma generating part 80, the Faraday shield 95, the casing 90 and the wafer W are partly enlarged.

After the rotation of the turntable 2, the Si containing gas is absorbed on the surface of the wafer W in the first process area P1. Further, after the rotation of the turntable 2, the Si containing gas absorbed on the wafer W in the second process area P2 is oxidized thereby forming a reaction product on which one or more molecular layer of silicon oxide (SiO₂) film are formed as a thin film. At this time, impurities such as moisture (OH radical) and an organic substance may be contained in the silicon oxide film due to a residual radical contained in the Si containing gas.

After the rotation of the turntable 2, the above-mentioned plasma (activated species) is applied to the surface of the plasma thereby performing alternation of the silicon oxide film. Specifically, the plasma crashes against the surface of the wafer W thereby causing the impurities to be discharged from the silicon oxide film or causing elements contained in the silicon oxide film to be rearranged for obtaining a highly dense silicon oxide film. Along with the rotation of the turntable 2, the absorption of the Si containing gas on the surface of the wafer W, the oxidization of the component of the Si containing gas absorbed on the surface of the wafer W, and the plasma alternation of the reaction product are repeated many times in this order thereby forming the thin film in which the reaction products are laminated. AS described, the electric wiring is formed inside the wafer W. However, the electric field is shielded by the Faraday shield provided between the plasma generating part 80 and the wafer W. Therefore, electric damage to the electric wiring can be prevented.

Within the embodiment, the Faraday shield 95 made of the grounded conductive material is provided between the plasma generating part 80 and the wafer W, and the slits 97 is opened on the Faraday shield 95 in the direction perpendicular to the loop of the antenna 83. The conductive paths 97a, 97a are formed along the one end and the other ends to the slits 97 along the loop of the antenna 83. Thus, not only the electric field downward directing from the plasma generating part 80 generated by the plasma generating part 80 but also the electric field downward directing via the one and other ends of the slits 97 in their longitudinal directions can be shielded by the Faraday shield 95. Meanwhile, the magnetic field can reach the inside of the vacuum chamber 1. Therefore, the alternation of the wafer W can be performed while suppressing the electric damage caused by the plasma to the electric wiring inside the wafer W. Thus, a good film quality and a good electric characteristic are obtainable.

Further, by providing the conductive paths 97a, 97a, the upper and lower stream sides of the rotational direction of the turntable 2 are close while shielding the electric field toward the wafer W. Further, the opening portion 98 for observing the plasma can be formed. Further, in comparison with the case where the antenna is shaped like a perfect circle, the dimension of the casing in the rotational direction of the turntable 2 can be reduced to thereby suppress the thickness of the casing 90. As a result, the amount of highly pure quartz used for the casing 90 can be suppressed thereby reducing the cost of the film deposition apparatus. Further, because the area of the casing 90 can be reduced, the capacity of the casing 90 is also reduced thereby minimizing a gas flow quantity for maintaining the inside of the plasma space 10 to be a positive pressure relative to the other portions of the vacuum chamber 1.

Further, since the Faraday shield 95 is provided, it is possible to suppress damage (etching) caused by the plasma to the parts made of quartz such as the casing 90. Therefore, the lifetime of the parts made of quartz can be elongated, generation of contamination can be prevented, and unevenness of the film thickness caused by contamination into the thin film of quartz (SiO₂) can be prevented.

Further, since the casing 90 is provided, the plasma generating part 80 can be close to the wafer W on the turntable 2. Therefore, even in high pressure atmosphere (a low degree of vacuum) for a film deposition process, deactivation of ions and radicals inside plasma can be suppressed to thereby perform good alternation. Further, since the protruding portion 92 is provided in the casing 90, the O-ring 11d is not directly exposed to the plasma space 10. Therefore, it is possible to prevent a fluorine component contained in the O-ring 11d from being mixed in the wafer W to thereby elongate the lifetime of the O-ring 11d.

Furthermore, the protruding portion 92 is formed below the lower surface of the casing 90 and the ejection hole 33 of the plasma generating gas nozzle 34 directs the upstream side of the rotational direction of the turntable 2. Therefore, even if the gas flow rate discharged from the plasma generating gas nozzle 34 is small, it is possible to prevent the O₃ gas and the N₂ gas from intruding below the casing 90. Then, the pressure of the area (the plasma space 10) where the plasma generating gas nozzle 34 is located is higher than the pressure of the other areas such as the processing areas P1 and P2. As described, generation of NOₓ gas in the plasma space can be suppressed to thereby suppress decomposition of parts caused by the NOₓ gas inside the vacuum chamber 1. Therefore, metal contamination of the wafer W can be prevented. Since the O₃ gas and the N₂ gas are prevented from intruding below the casing 90, an evacuation port or a pump are not separately provided between the casing 90 and the second process gas nozzle 32 in simultaneously performing a film deposition process and a alternation process by one film deposition apparatus, a separation area D needs not be provided between the casing 90 and the nozzle 32 thereby simplifying the structure of the film deposition apparatus.

Further in arranging the casing 90, the gas flow route 101 is formed in the side ring 100 which is provided on the outer peripheral side of the casing 90. Therefore, the gases are preferably exhausted without passing through the casing 90.

Furthermore, since the plasma generating part 80 is accommodated inside the casing 90, the plasma generating part 80 can be arranged in an area of atmosphere of air (an outer area of the vacuum chamber 1). Therefore, maintenance of the plasma generating part 80 is facilitated.

Since the plasma generating part 80 is accommodated inside the casing 90, the end of the plasma generating part 80 on the side of the center area C is separated from the rotation center of the turntable 2 by a thickness of the sidewall of the casing 90. Therefore, plasma does not easily reach the end of the wafer W on the center area C. On the other hand, if the casing 90 (the plasma generating part 80) is formed at a position closer to the center area C so that plasma reaches an end portion of the wafer W on the side of the center area C, the center area C is narrowed as described above. In this case, the process gases may be mixed in the center area C. However, within the embodiment, the labyrinth structure 110 is formed in the center area C to extend the flow passage. Therefore, while maintaining the wide plasma space along the radius direction of the turntable 2, it is possible to prevent the process gases from mixing and prevent the N₂ gas from intruding into the plasma space 10.

Although the film formation of the reaction product and the reformation process of the reaction product are alternately performed, after laminating 70 layers of the reaction products to be the film thickness of about 10 nm, an alternation process may be performed for this laminated body of the reaction products. Specifically, while the film deposition process of the reaction products is performed by supplying the Si containing gas and the O₃ gas, supply of the high-frequency power to the plasma generating part 80 is stopped. After forming the laminated body, the supply of the Si containing gas and the supply of the O₃ gas is stopped and the high-frequency power is supplied to the plasma generating part 80. Such reformation may be called “simultaneous alternation”. In this simultaneous alternation, effects similar to the above alternation are obtainable.

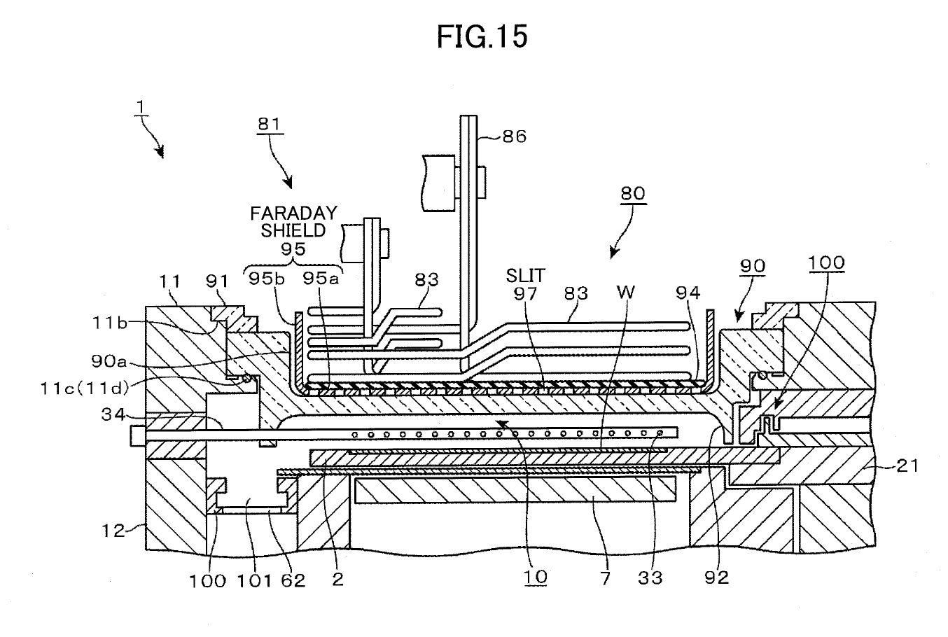

Other examples of the film deposition apparatus are described. FIG. 15 illustrates an auxiliary plasma generating part 81 for increasing a plasma density on the outer peripheral side of the turntable 2 which is provided in the film deposition apparatus in addition to the plasma generating part 80. When the turntable 2 rotates, the peripheral speed on the outer peripheral side is higher than the peripheral speed on the center side. Therefore, the degree of reformation on the outer peripheral side becomes smaller than the degree of reformation on the center side. In order to match the degrees of reformation along the radius direction of the turntable 2, the auxiliary plasma generating part 81 is provided. The auxiliary plasma generating part 81 includes an antenna 83 wound at the outer peripheral side of the plasma generating part 80. In this example, the plasma generating part 80 and the auxiliary plasma generating part 81 have sets of slits and pairs of conductive paths, respectively, to thereby shield electric field directing a wafer W.

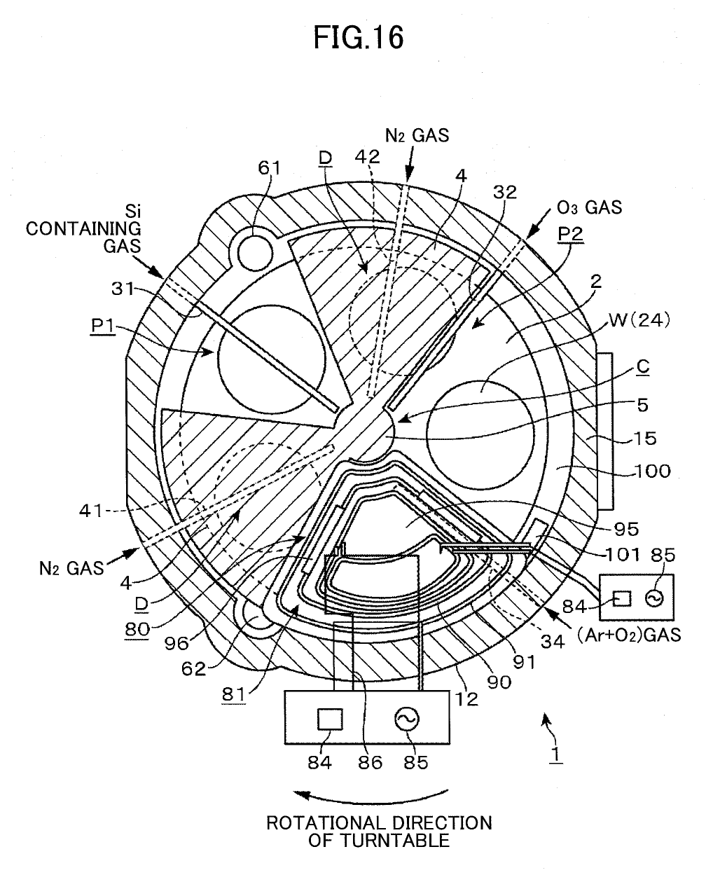

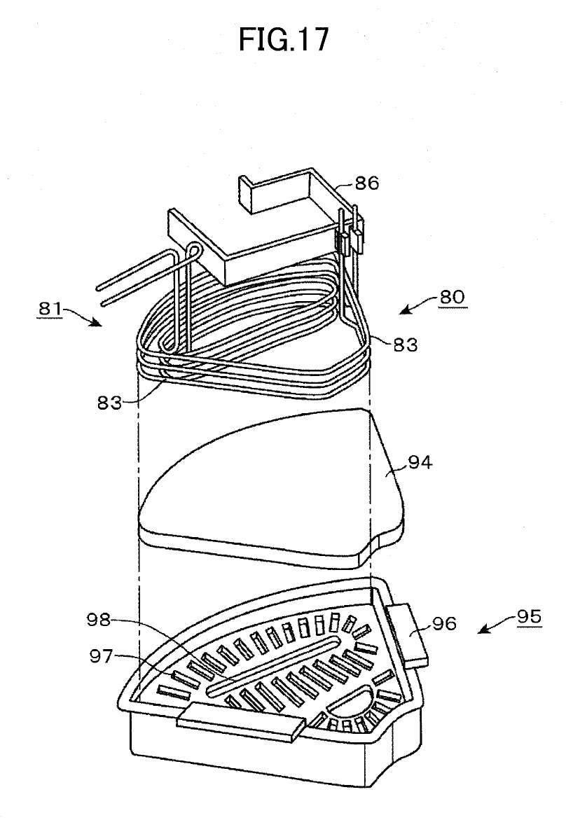

Further, referring to FIG. 16 and FIG. 17, the plasma generating part 80 may be substantially in a sector-like shape in a manner similar to that of the casing 90. Referring to FIG. 16, the plasma generating part 80 and the auxiliary plasma generating part 81 are shaped like sectors. In this example, the slits 97 are arranged along loops of the antennas 83 of the plasma generating part 80 and the auxiliary plasma generating part 81, respectively. The conductive paths 97a are formed in the plasma generating part 80 and the auxiliary plasma generating part 81, respectively. In this example, the lengths of the slits 97 at bent portions where the loops of the antenna turns (the upstream and downstream sides in the rotational direction of the turntable 2 on the side of the center area C of the turntable 2) cannot be sufficiently long in a manner similar to the above example. Then, the conductive paths 97a are provided to shield the electric field downward directing from the bent portions. The sector-like shapes of the plasma generating part 80 and the auxiliary plasma generating part 81 make densities of plasma higher than those in the center portions of the plasma generating part 80 and the auxiliary plasma generating part 81. Therefore, it is possible to further equalize the degrees of alternation throughout the surface of the wafer W. Referring to FIG. 16, the slits 97 are omitted.

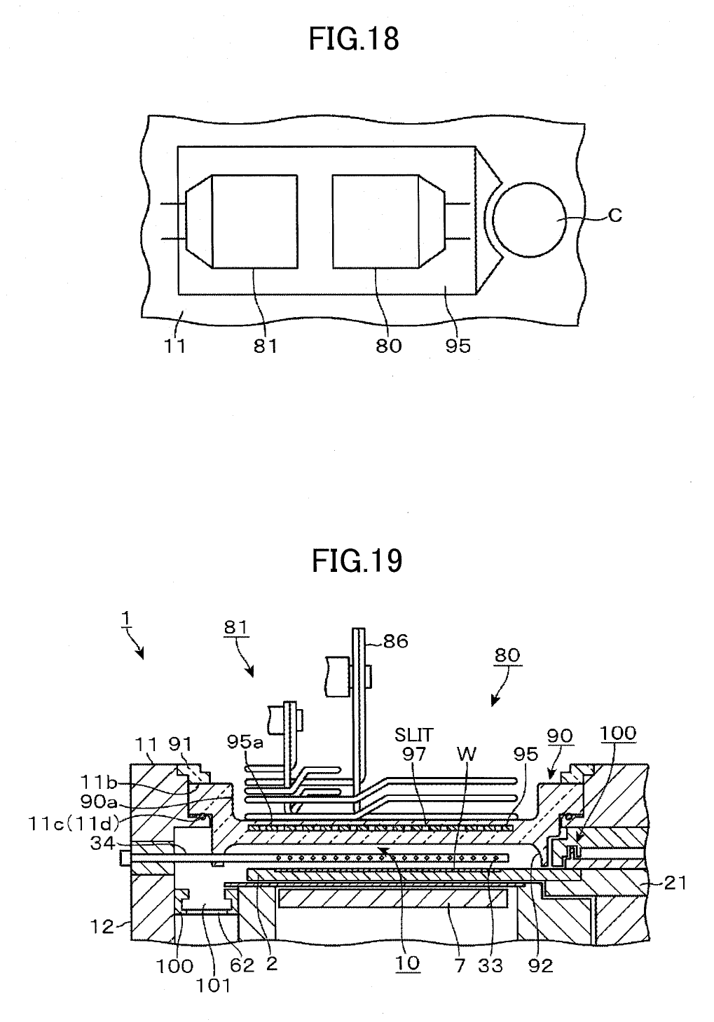

Referring to FIG. 18, outlines of plasma generating part 80 are shaped like a rectangular. The plasma generating part 80 is arranged on the inside of the radius direction of the turntable 2. A plasma generating part 81 is arranged on the outside of the radius direction of the turntable 2. The area occupied by the outline of the plasma generating part 80 and the area occupied by the outline of the plasma generating part 81 are substantially the same. FIG. 18 is a partial plan view schematically illustrating the ceiling plate 11, the plasma generating parts 80 and 81 including the antennas 83.

Referring to FIG. 19, the Faraday shield 95 is embedded inside the casing 90. Specifically, a casing 90 below the plasma generating part 80 has an upper surface which is detachable. A Faraday shield 95 is accommodated in a portion of the casing 90 from which the upper surface is detached. The Faraday shield 95 may be provided between the plasma generating part 80 and the wafer W.

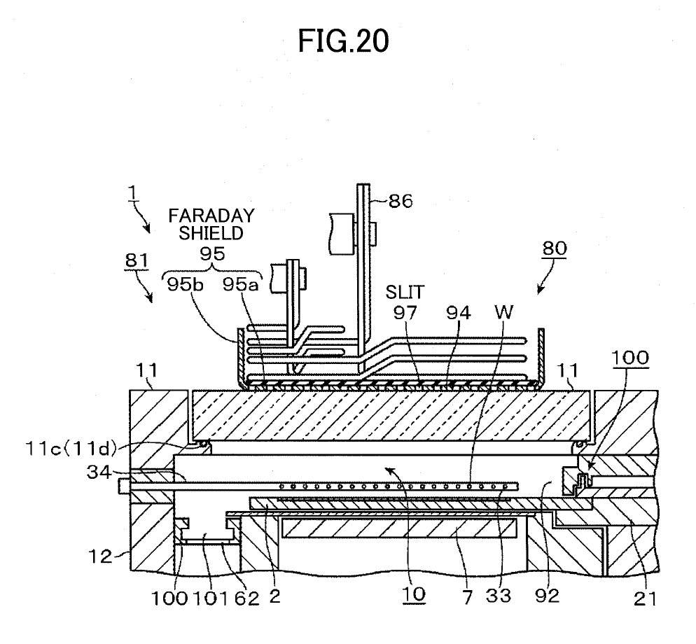

FIG. 20 illustrates an example in which the casing 90 is not provided. Instead of accommodating the plasma generating part 80 and the Faraday shield 95 inside the casing 90, the plasma generating part 80 and the Faraday shield 95 are arranged above the ceiling plate 11. A part of the ceiling plate 11 below the plasma generating part 80 may be made of a dielectric material such as quartz. A peripheral portion on the lower side of the ceiling plate 11 is hermetically connected to the other portions of the ceiling plate 11 by an O-ring 11d along peripheral directions of the ceiling plate.

Slits 97 on the center side of the turntable are separated from slits 97 on the outer peripheral side of the turntable 2 are separated by a distance corresponding to the diameter of a wafer W. Therefore, an electric field can be shielded on a wide area. Therefore, a conductive path 97a may not be provided. Further, in an area where the antennas 83 on the upstream and downstream sides in the direction of the turntable, an area where one or the other ends of the slits 97 are opened without the conductive path 97a may be provided as long as the magnetic field negatively influences within an allowable extent.

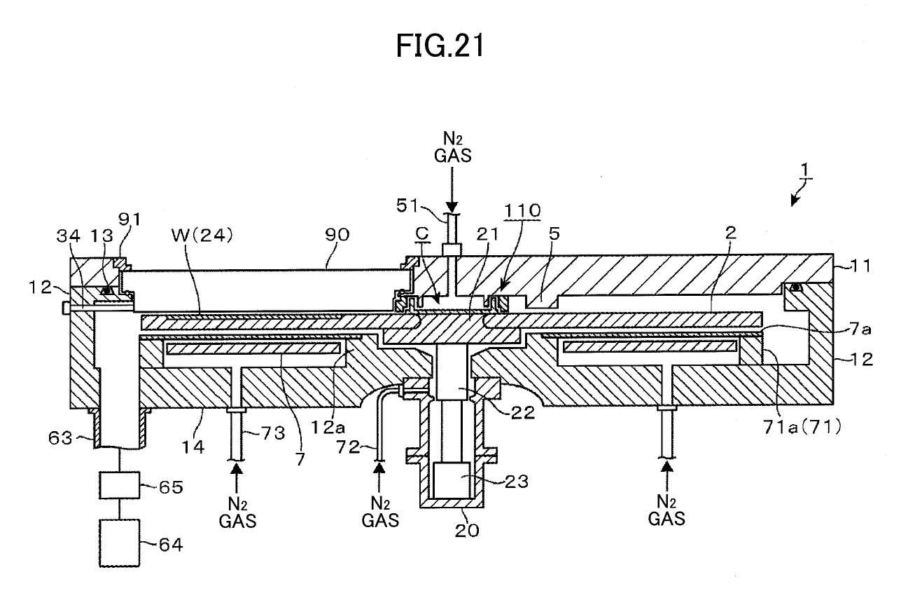

FIG. 21 illustrates an example in which a side ring 100 is not arranged. Said differently, the side ring 100 is provided to prevent a cleaning gas used for cleaning the film deposition apparatus from reaching below the turntable 2. Therefore, the side ring 100 may not be provided when the cleaning is not performed.

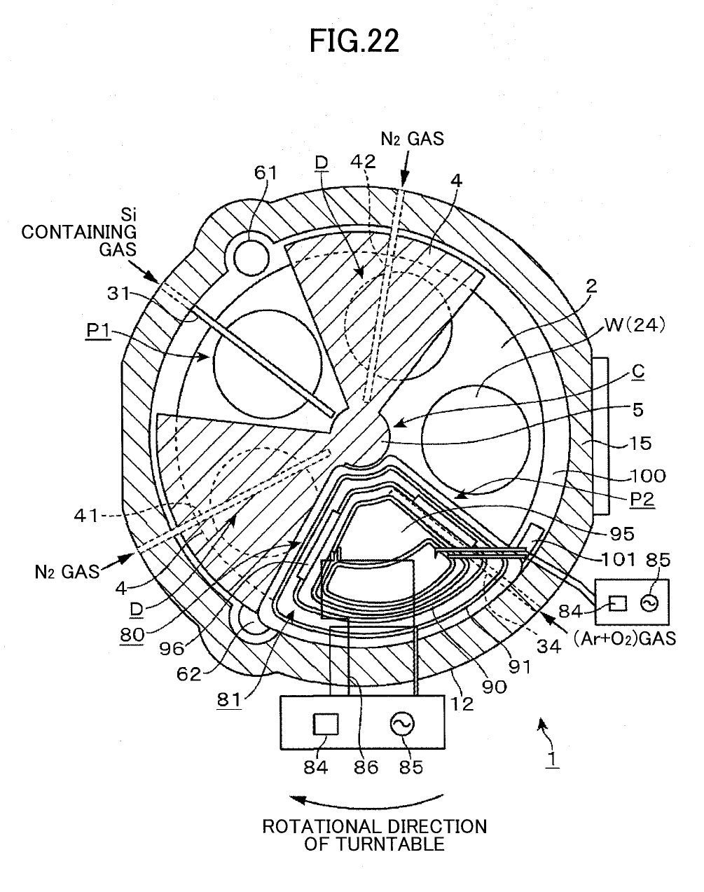

The example of performing alternation of the reaction product by the plasma generating part 80 after the reaction products are formed by supplying the Si containing gas and the O₃ gas on the wafer W in this order was described above. However, the O₃ gas used to form the reaction products may be converted to plasma. Referring to FIG. 22, a process gas nozzle 32 is not provided. The Si containing gas absorbed on the wafer W is oxidized in a plasma space 10 to form the reaction products to thereby reform the reaction products in the plasma space 10. Said differently, the plasma generating gas supplied to the plasma space 10 is a second process gas. Therefore, the plasma generating gas nozzle 34 is used also as the process gas 32. As described, by oxidizing the Si containing gas absorbed on the surface of the wafer W in the plasma space 10, an ozonizer of the process gas nozzle 32 becomes unnecessary to thereby reduce the cost of the plasma forming apparatus. By generating the O₃ gas immediately above the wafer W, the length of the flow passage of the O₃ gas can be reduced by, for example, the length of the process gas nozzle 32. Therefore, deactivation of the O₃ gas can be suppressed to preferably enable oxidation of Si.

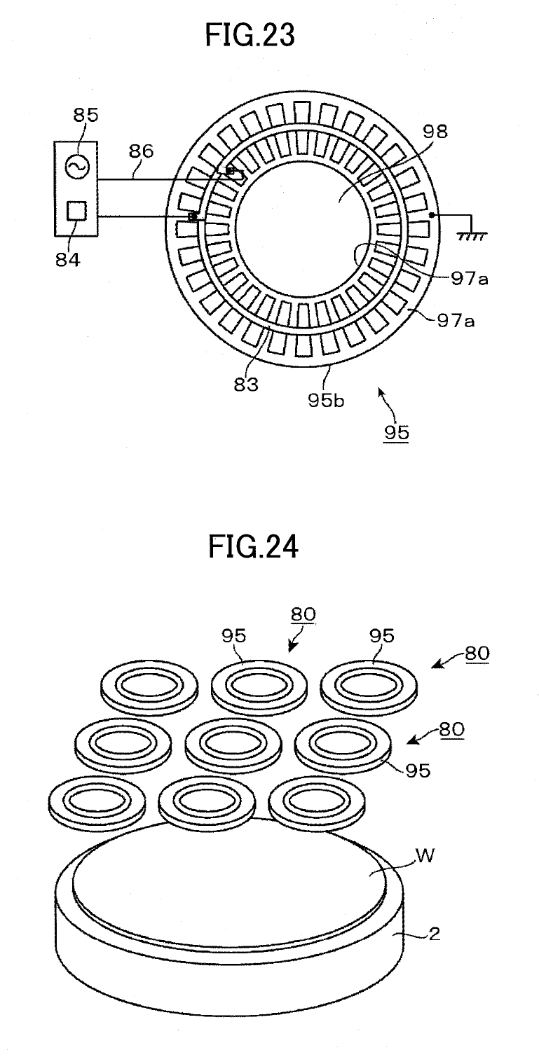

Within the above examples, the antennas 83 are formed to be substantially an octagon or a sector in a plan view of the antennas 83. However, the antennas 83 may be shaped like a circle as illustrated in FIG. 23. In this case also, slits 97 are arranged along the peripheral direction of the antenna 83, and conductive paths 97a, 97a are arranged on inner or outer peripheral sides of the slits 97. The area surrounded by the conductive path 97a on the inner peripheral side includes an opening portion 98. Referring to FIG. 23, the antenna 83 and a Faraday shield 95 are schematically illustrated.

In a case where the circular antenna 83 is used, the circular antenna 83 may be used instead of the antenna 83 illustrated in FIG. 3. For example, as illustrated in FIG. 15, the two antennas may be arranged in the radius direction of the turntable 2. Further, plural circular antennas 83 may be arranged above the plasma space 10. Said differently, even if the antenna 83 is circular and the diameter of the antenna 83 is, for example, about 150 mm or smaller, the lengths L of the slits 97 may not be sufficient to shield the electric field downward directing from the antenna 83. Therefore, in a case where such antenna 83 having a small diameter is used, an electric field downward directing from the antenna 83 can be shielded by providing conductive paths 97a, 97a on inner and outer edge sides, respectively.

In a case where the circular antennas 83 are used for a film deposition apparatus as illustrated in FIG. 23 and FIG. 24, wafers W having a size of 300 mm or 450 mm are mounted on a table 2 and plasma generating parts 80 are arranged to face the wafer W so that plasma is applied to the wafer W. Referring to FIG. 24, the plasma generating parts 80 and the Faraday shields 95 are schematically illustrated so that the plasma generating parts 80 equal to nine are arranged on a grid of 3 rows and 3 columns. Referring to FIG. 24, a vacuum chamber in which the wafer W is accommodated or the like is omitted.

In this case, after forming the reaction product (a film) on the wafer W using one type of a film forming gas or two types of mutually reactive process gases supplied from a process gas supplying path (not illustrated), the inside of a vacuum chamber 1 is exhausted to be a vacuum, and a plasma generating gas supplied into the vacuum chamber 1 is converted to plasma thereby reformulating the reaction product.

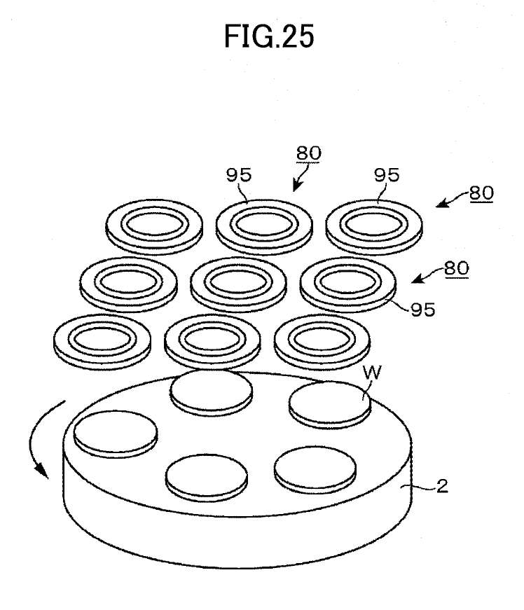

Further, when the plasma generating part 80 illustrated in FIG. 23 is used, five wafers W having a diameter of, for example, 8 inches (200 mm) are arranged on the turntable 2 as illustrated in FIG. 25. Plural plasma generating parts 80 are arranged to face the wafers W. In this case, a film deposition process and an alternation process are provided to the wafers W while the turntable 2 is rotated around a vertical axis. This film deposition apparatus is used to form a power device for a Light Emitting Diode (LED) on the wafer W.

Furthermore, within the above examples, the plasma generating part 80 is combined with the film deposition apparatus 80 to perform the film deposition process and the plasma process. However, the plasma process may be performed for the wafer W subjected to the film deposition process. In this case, the above film deposition apparatus is provided with a loading table (not illustrated) inside the vacuum chamber 1. Further, the plasma generating gas nozzle 34 and the plasma generating device (the antenna 83 and the Faraday shield 95) are provided so as to be structured as a substrate processing apparatus. The substrate processing apparatus performs alternation for the thin film on the wafer W formed by the film deposition apparatus using magnetic filed.

A material forming the Faraday shield 95 preferably has a relative magnetic permeability as low as possible to enable the magnetic field to pass through the Faraday shield 95. Specifically, the material may be silver (Ag), aluminum (Al) or the like. As the number of the slits 97 of the Faraday shield 95 is smaller, the magnetic field reaching inside the vacuum chamber 1 becomes smaller. On the other hand, as the number of the slits 97 of the Faraday shield 95 is larger, it becomes more difficult to produce the Faraday shield 95. Therefore, the number of the slits 97 of the Faraday shield 95 is preferably about 100 to 500 per the length of the antenna 83 of 1 m. Further, the ejection hole 33 of the plasma generating gas nozzle 34 is arranged to direct an upstream side of the rotational direction of the turntable 2. However, the ejection hole 33 may be arranged to direct a downstream side of the rotational direction of the turntable 2 or direct downward.

The material of the casing may be alumina (Al₂O₃) or an anti-plasma etching material such as yttria instead of quartz. For example, the anti-plasma etching material may be coated on a surface of Pyrex glass (“Pyrex” is a registered trademark), heat-resistance glass manufactured by Corning Incorporated. The casing 90 has high durability against plasma and is made of a material through which a magnetic field passes such as a dielectric material.

Further, the insulating plate 94 may be arranged above the Faraday shield 95 to insulate the Faraday shield 95 from the antenna 83 (the plasma generating part 80). However, the antenna 83 may be coated by an insulating material such as quartz without arranging the insulating plate 94.

Further, the silicon oxide film is formed using the Si containing gas and the O₃ gas in the above example. A silicon nitride film may be formed using the Si containing gas and ammonia (NH₃) gas as first and second process gases, respectively. In this case, the process gas for generating plasma may be an argon gas, a nitrogen gas, or an ammonia gas.

Further, for example, the first and second process gases may be a titanium chloride (TiCl₂) gas and the ammonia gas, respectively to thereby form a titanium nitride film. In this case, the wafer W is a substrate made of titanium, and the plasma generating gas is an argon gas or a nitrogen gas. The process gases equal to 3 types or greater may be sequentially supplied to laminate the reaction products. Specifically, an Sr raw material such as strontiumbis-tetramethylheptanedionato (Sr(THD)₂) and bis(pentamethyl)cyclopentadienestrontium (Sr(Me5 Cp)₂) and a Ti raw material such as titaniumbis(isopropoxide)bis-tetramethylheptanedionato (Ti(OiPr)₂(THD)₂) and titaniumtetra-isopropoxide (Ti(OiPr)) are supplied to the wafer W. Thereafter, the O3 gas is supplied to the wafer W to thereby a thin film made of an STO film being an oxide film containing Sr and Ti.

Further, although the N₂ gas is supplied to the separating area D from the gas nozzles 41 and 42, the gas nozzles 41 and 42 may not be provided. In this case, a wall for separating the processing areas P1 and P2 is provided as the separating area D.

Further, the antenna 83 is arranged in an area which is hermetically separated from the internal area of the vacuum chamber 1 such as the inside of the casing 90 and the upper surface of the casing 90. However, the antenna 83 may be arranged inside the vacuum chamber 1. Specifically, the antenna 83 may be formed slightly below the lower surface of the ceiling plate 11. In this case, the surface of the antenna 83 is coated by a dielectric material such as quartz to prevent the antenna 83 from being etched by plasma. In this case, a part of the surface of the Faraday shield 95 between the antenna 83 and the wafer W is coated by a dielectric material such as quartz to prevent the Faraday shield 95 from being etched by plasma. Further, although the antenna 83 is wound around a vertical axis, the loop of the antenna may be wound around an axis oblique to the vertical axis or an axis obliquely vertical to the horizontal surface of the Faraday shield 95.

In the above example, in order to protect the inner wall surface and the ceiling plate 11 of the vacuum chamber 1 from the various process gases including the cleaning gases supplied from the nozzles 31 and 32, a protective cover (not illustrated) is provided on a side of processing atmosphere relative to the inner wall surface and the ceiling plate 11 interposing a gap.

A purge gas is supplied from a gas supplying portion (not illustrated) in the gap to make the pressure inside the gap be a positive pressure slightly higher than that in the processing atmosphere. However, description of this is omitted. Experimental examples of embodiment

Hereinafter, an experimental example using the film deposition apparatus illustrated in FIG. 1 is described.

### Experimental Example 1

Six types of dummy wafers having different permissibility of electrical damage are prepared. Plasma is applied to the wafers via a following Faraday shield. Electric damage to gate oxide films of devices formed on the wafers W is evaluated. Detailed experiment conditions for the embodiment and comparative example are omitted.

### Faraday Shield Used for the Experiments

### Comparative Example

a Faraday shield in a comb-like shape in which a conductive path 97a is not provided in inner peripheral sides of slits

### Embodiment

the Faraday shield 95 illustrated in FIG. 8

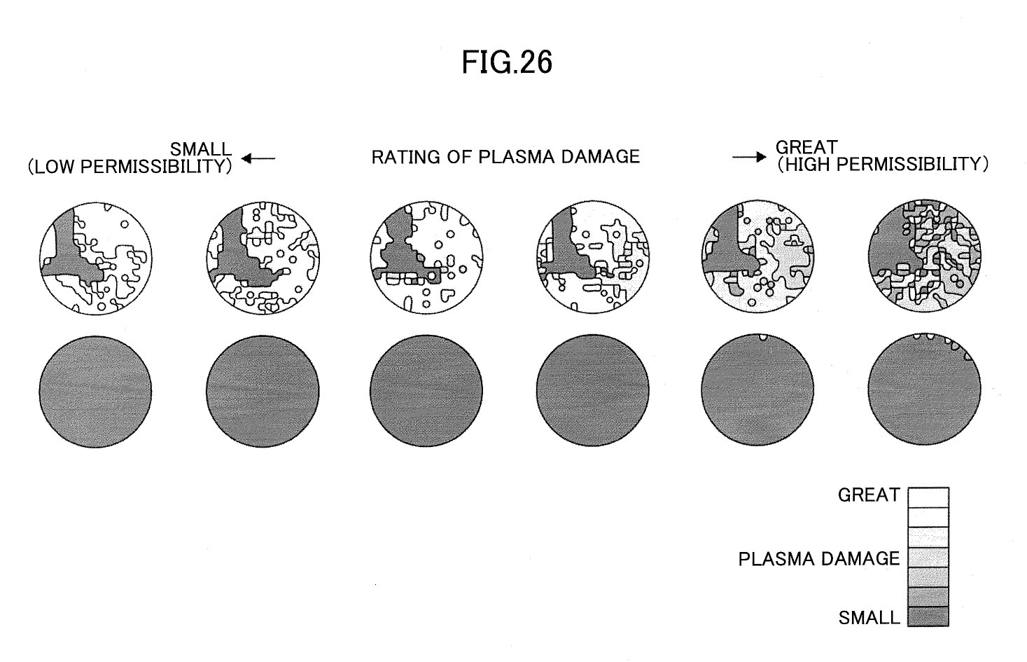

When the Faraday shield without the conductive path 97a of the comparative example is experimented, electric damage to wafers occurs as illustrated in the upper half of FIG. 26. In the upper half of FIG. 26, the wafer on the right end has the highest permissibility, and the permissibility of the wafers is lowered in the left direction. On the other hand, when the Faraday shield 95 having the conductive paths 97a, 97a of the embodiment is used, electric damage to the wafers is very small as illustrated in the lower half of FIG. 26. Therefore, it is known that insulation breakdown of the gate oxide film is suppressed by providing the Faraday shield 95 illustrated in FIG. 8.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments. Although the claims have been described in detail, it should be understood that the various changes, substitutions, and alterations could be made hereto without departing from the spirit and scope of the invention.

What is claimed is:

1. A film deposition apparatus which forms a film on a substrate by repeatedly performing a process of sequentially supplying a first process gas containing Si and a second process gas containing O₂ inside a vacuum chamber, the film deposition apparatus comprising:
a turntable including a substrate mounting area formed on one surface of the turntable to mount a substrate, the turntable being configured to rotate the substrate mounting area inside the vacuum chamber;
a first process gas supplying portion for supplying the first process gas to a first area over the turntable;
a second process gas supplying portion for supplying the second process gas to a second area over the turntable, the second area being separated, in a peripheral direction of the turntable, from the first area by a separating area being provided over the turntable and interposing between the first area and the second area;
a plasma generating gas supplying portion protruding inside the vacuum chamber to supply a plasma generating gas containing Ar and O₂ used for applying plasma to the substrate inside the vacuum chamber;
an antenna facing the substrate mounting area and being wound toward a direction perpendicular to the one surface of the turntable, the antenna being configured to convert the plasma generating gas to plasma using induction coupling; and
a Faraday shield intervening between the antenna and the substrate and being made of a conductive plate which is grounded to prevent an electric field included in an electromagnetic field, which is generated around the antenna, from passing through the Faraday shield including:
slits arranged on the conductive plate parallel to a loop of the antenna, the slits being opened on the conductive plate in directions perpendicular to a direction of arranging the slits to enable a magnetic field included in the electromagnetic field to reach the substrate,
a window opened in an area of the conductive plate surrounded by the slits, the window is configured to enable observation of generation of the plasma,
an inner conductive path which is formed between the slits and the window and grounded so as to prevent the window from communicating the slits, and
an outer conductive path which is formed on a side opposite to the window relative to the slits and surrounds the slits.

2. The film deposition apparatus according to claim 1,
wherein the loop of the antenna is arranged so as to surround the window.

3. The film deposition apparatus according to claim 1,
wherein the antenna and the Faraday shield are hermetically separated from an area for applying the plasma to the substrate.

4. A substrate processing apparatus comprising:
a vacuum chamber configured to accommodate a substrate;
a loading table including a substrate mounting area formed on one surface of the loading table to mount a substrate;
a plasma generating gas supplying portion protruding inside the vacuum chamber to supply a plasma generating gas containing Ar and O₂ used for applying plasma to the substrate inside the vacuum chamber;
an antenna facing the substrate mounting area and being wound toward a direction perpendicular to the one surface of the loading table, the antenna being configured to convert the plasma generating gas to plasma using induction coupling; and
a Faraday shield intervening between the antenna and the substrate and being made of a conductive plate which is grounded to prevent an electric field included in an electromagnetic field, which is generated around the antenna, from passing through the Faraday shield including:
slits arranged on the conductive plate parallel to a loop of the antenna, the slits being opened on the conductive plate in directions perpendicular to a direction of arranging the slits to enable a magnetic field included in the electromagnetic field to reach the substrate,
a window opened in an area of the conductive plate surrounded by the slits, the window is configured to enable observation of generation of the plasma,
an inner conductive path which is formed between the slits and the window and grounded so as to prevent the window from communicating the slits, and
an outer conductive path which is formed on a side opposite to the window relative to the slits and surrounds the slits.

5. A plasma generating device that generates plasma used for applying the plasma to a substrate, the plasma generating device comprising:
an antenna facing the substrate and being wound toward a direction perpendicular to one surface of the substrate, the antenna being configured to convert a plasma generating gas containing Ar and O₂ to plasma using induction coupling; and
a Faraday shield intervening between the antenna and the substrate and being made of a conductive plate which is grounded to prevent an electric field included in an electromagnetic field, which is generated around the antenna, the Faraday shield including:
slits arranged on the conductive plate parallel to a loop of the antenna, the slits being opened on the conductive plate in directions perpendicular to a direction of arranging the slits to enable a magnetic field included in the electromagnetic field to reach the substrate,
a window opened in an area of the conductive plate surrounded by the slits, the window is configured to enable observation of generation of the plasma,
an inner conductive path which is formed between the slits and the window and grounded so as to prevent the window from communicating the slits, and
an outer conductive path which is formed on a side opposite to the window relative to the slits and surrounds the slits.
